(19) United States
(12) Patent Application Publication
(10) Pub. No.: US 2026/0173962 A1
(43) Pub. Date: Jun. 18, 2026

(54) STACKED INTEGRATED CIRCUIT DEVICE INCLUDING A STIFFENER DIE

(71) Applicant: QUALCOMM Incorporated, San Diego, CA (US)

(72) Inventors: Mustafa BADAROGLU, San Diego, CA (US); Roger BOOTH, San Diego, CA (US); Jihong CHOI, San Diego, CA (US); Yangyang SUN, San Diego, CA (US); Xiaonan CHEN, San Diego, CA (US); Hyun LEE, San Diego, CA (US); Jaekyu SONG, San Diego, CA (US); Zhongze WANG, San Diego, CA (US); Woo Tag KANG, San Diego, CA (US); Giridhar NALLAPATI, San Diego, CA (US); Periannan CHIDAMBARAM, San Diego, CA (US)

(21) Appl. No.: 19/214,805

(22) Filed: May 21, 2025

Related U.S. Application Data
(60) Provisional application No. 63/735,075, filed on Dec. 17, 2024.

(51) Int. Cl. H01L 25/07; H01L 25/00; H01L 25/16; H10B 80/00

(52) U.S. Cl. CPC H10W 90/00; H10B 80/00; H10W 90/297

(57) ABSTRACT

A package includes a first die, a second die, and a third die. The first die includes first active circuitry, and a first plurality of conductive vias (CVs) that has a first pitch. The second die includes second active circuitry proximate to a first side of the second die. The second active circuitry includes metal layers and a second plurality of CVs that extends from a second side of the second die to one or more of the metal layers. The second plurality of CVs has a second pitch greater than the first pitch. The third die includes a third plurality of CVs to electrically couple the second active circuitry to a substrate. The third plurality of CVs has a third pitch greater than the first pitch. The second die is disposed between the first die and the third die.

### CROSS-REFERENCE TO RELATED APPLICATIONS

The present application claims priority from Provisional Patent Application No. 63/735,075, filed Dec. 17, 2024, entitled “STACKED INTEGRATED CIRCUIT DEVICE INCLUDING A STIFFENER DIE,” the content of which is incorporated herein by reference in its entirety.

### FIELD

Various features relate to stacked integrated circuit devices.

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

In state-of-the-art electronic devices, there is generally an expectation that integrated device packages have a small form factor, a low cost, a tight power budget, structural integrity, and high performance. These various goals are often in conflict. For example, in three dimensional (3D) stacking, via-last access can be employed to form conductive vias that extend from a back side of a die to metal layers of active circuitry on a front side of the die. Routing signals through conductive vias that extend from the back side to land at a metal layer (e.g., Metal 1 layer) that is closest to the back side enables more space efficient use of the metal layer (e.g., Metal 2 and higher layers) closer to the front side of the die. Due to processing constraints, it is challenging to form conductive vias that land on the Metal 1 layer unless the die is thinned significantly. However, such significant thinning of the die can lead to other problems, such as delamination due to flexibility of the thinned die. Thus, reducing the form factor of a stacked die device can result in increased cost of the device due to reduced manufacturing yield.

### SUMMARY

Various features relate to integrated circuit devices.

One example provides a package that includes a first die, a second die electrically coupled to the first die, and a third die electrically coupled to the second die. The first die includes first active circuitry. The first die also includes a first plurality of conductive vias that has a first pitch. The second die includes second active circuitry proximate to a first side of the second die. The second active circuitry includes a plurality of metal layers. The second die also includes a second plurality of conductive vias that extends from a second side of the second die to one or more of the plurality of metal layers. The second plurality of conductive vias has a second pitch that is greater than the first pitch. The third die includes a third plurality of conductive vias to electrically couple the second active circuitry to a substrate. The third plurality of conductive vias has a third pitch that is greater than the first pitch. The second die is disposed between the first die and the third die.

Another example provides a method of fabrication that includes electrically coupling a first die to a second die. The first die includes first active circuitry. The first die also includes a first plurality of conductive vias having a first pitch. The second die includes second active circuitry proximate to a first side of the second die. The second active circuitry includes a plurality of metal layers. The second die includes a second plurality of conductive vias that extends from a second side of the second die to one or more of the plurality of metal layers. The second plurality of conductive vias has a second pitch that is greater than the first pitch. The method also includes electrically coupling a third die to the second die. The third die includes a third plurality of conductive vias to electrically couple the second active circuitry to a substrate. The third plurality of conductive vias has a third pitch that is greater than the first pitch.

Another example provides a method of fabrication that includes electrically coupling a first wafer to a second wafer. The method also includes electrically coupling the second wafer to a third wafer. The method also includes singulating a package. The package includes a first die formed from the first wafer, a second die formed from the second wafer, and a third die formed from the third wafer. The first die includes first active circuitry. The first die also includes a first plurality of conductive vias having a first pitch. The second die includes second active circuitry proximate to a first side of the second die. The second active circuitry includes a plurality of metal layers. The second die also includes a second plurality of conductive vias that extends from a second side of the second die to one or more of the plurality of metal layers. The second plurality of conductive vias has a second pitch that is greater than the first pitch. The third die includes a third plurality of conductive vias to electrically couple the second active circuitry to a substrate. The third plurality of conductive vias has a third pitch that is greater than the first pitch.

### BRIEF DESCRIPTION OF THE DRAWINGS

Various features, nature and advantages may become apparent from the detailed description set forth below when taken in conjunction with the drawings in which like reference characters identify correspondingly throughout. It is noted that one or more figures are annotated with X-, Y-, and/or Z-axes to facilitate recognition of the orientation illustrated in each view.

FIG. 1 illustrates a cross-sectional profile view of an exemplary stacked IC device including a stiffener die.

FIG. 2 illustrates a cross-sectional profile view of another exemplary stacked IC device including a stiffener die.

FIG. 3A illustrates a first part of an exemplary sequence for fabricating a die stack that includes multiple dies that include active circuitry.

FIG. 3B illustrates a second part of the exemplary sequence for fabricating a die stack that includes multiple dies that include active circuitry.

FIG. 4A illustrates a first part of an exemplary sequence for fabricating the exemplary device of FIG. 1.

FIG. 4B illustrates a second part of the exemplary sequence for fabricating the exemplary device of FIG. 1.

FIG. 4C illustrates a third part of the exemplary sequence for fabricating the exemplary device of FIG. 1.

FIG. 4D illustrates an alternative third part of the exemplary sequence for fabricating the exemplary device of FIG. 1.

FIG. 4E illustrates a fourth part of the exemplary sequence for fabricating the exemplary device of FIG. 1.

FIG. 4F illustrates a fifth part of the exemplary sequence for fabricating the exemplary device of FIG. 1.

FIG. 5A illustrates a first part of an exemplary sequence for fabricating the exemplary device of FIG. 2.

FIG. 5B illustrates a second part of the exemplary sequence for fabricating the exemplary device of FIG. 2.

FIG. 5C illustrates a third part of the exemplary sequence for fabricating the exemplary device of FIG. 2.

FIG. 5D illustrates an alternative third part of the exemplary sequence for fabricating the exemplary device of FIG. 2.

FIG. 5E illustrates a fourth part of the exemplary sequence for fabricating the exemplary device of FIG. 2.

FIG. 5F illustrates a fifth part of the exemplary sequence for fabricating the exemplary device of FIG. 2.

FIG. 6A illustrates a cross-sectional profile view of a portion of the exemplary device of FIG. 1.

FIG. 6B illustrates a cross-sectional profile view of a portion of the exemplary device of FIG. 2.

FIG. 7 illustrates an exemplary flow diagram of a method of fabrication for a device that includes a conductive via in an intermediate die that extends from a side to the closest active circuitry metal layer of the die.

FIG. 8 illustrates an exemplary flow diagram of another method of fabrication for a device that includes a conductive via in an intermediate die that extends from a side to the closest active circuitry metal layer of the die.

FIG. 9 illustrates various electronic devices that may integrate an exemplary device that includes a conductive via in an intermediate die that extends from a side to the closest active circuitry metal layer of the die described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, components and circuitry may be shown in block diagrams in order to avoid obscuring the aspects in unnecessary detail. In other instances, well-known structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

In some drawings, multiple instances of a particular type of feature are shown. In some circumstances, fewer than all of such features may be identified using a reference number. For example, a single reference number may be shown and associated with a representative instance of the feature so as not to obscure other aspects of the drawings.

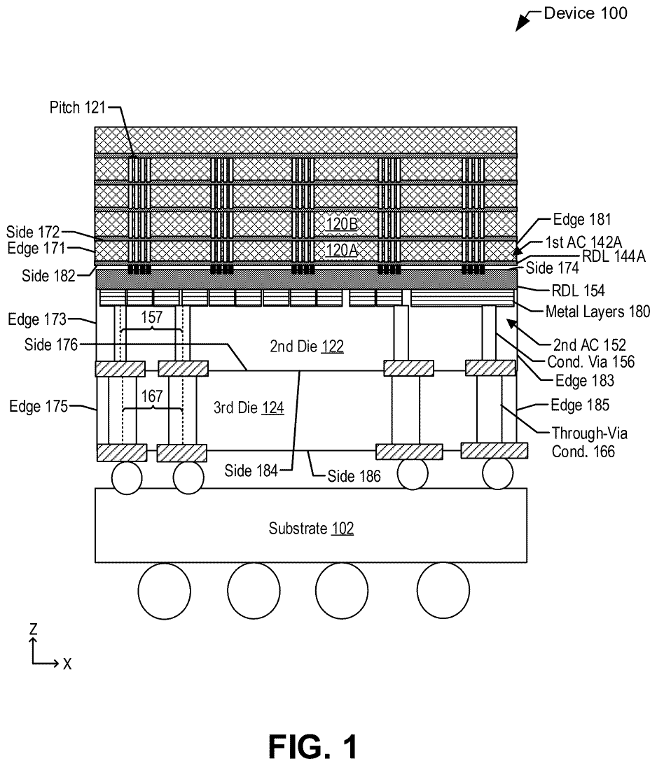

In some drawings in which multiple instances of a particular type of feature are used, different instances are distinguished by addition of a letter to the reference number. In this case, when the features as a group or a type are referred to herein (e.g., when no particular one of the features is being referenced), the reference number is used without a distinguishing letter. However, when one particular feature of multiple features of the same type is referred to herein, the reference number is used with the distinguishing letter. For example, referring to FIG. 1, multiple first dies are illustrated and associated with reference numbers 120A and 120B. When referring to a particular one of these first dies, such as a first die 120A, the distinguishing letter “A” is used. However, when referring to any arbitrary one of these first dies or to these first dies as a group, the reference number 120 is used without a distinguishing letter.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art device.

These interconnections include back-end-of-line (BEOL) interconnect layers, which may refer to the conductive interconnect layers for electrically coupling to front end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle of-line (MOL) interconnect layers, which interconnect to the FEOL active devices of an IC.

State-of-the-art electronic devices (e.g., portable computing devices, mobile communication devices, wearable devices, special purpose computing devices, etc.) demand a small form factor, low cost, a tight power budget, and high electrical performance. Integrated circuit package design has evolved to meet these divergent goals. One approach to reducing package size is to integrate multiple dies within a single package. One example of a multi-die package is a two-dimensional (2D) package architecture, in which two or more dies are coupled to a package substrate side-by-side with one another. Dies in this configuration can interact with one another (e.g., via die-to-die connections) and with off-package devices (e.g., via off-package connections). A challenge of such configurations is that die-to-die and off-package connections have different design criteria. For example, off-package connections are generally larger (e.g., in terms of line width, line spacing, etc.) than is needed for die-to-die connections. Various workarounds have been used to address this size difference. For example, additional devices (e.g., interposer devices or bridge die) can be added to a package to route die-to-die connections using smaller lines. As another example, additional layers or a separate stacked substrate can be added to the package substrate to provide die-to-die connection and redistribution routing to connect to off-package connections.

Another approach to reducing package size is a 2.5D architecture, in which two or more devices are positioned side-by-side with one another on the package substrate, and one or more additional devices are stacked on at least one of the side-by-side devices. To illustrate, a stacked die arrangement can be coupled to a package substrate side-by-side with another die, a passive device, another die stack, etc. Stacked die schemes and chiplet architectures are becoming more common as significant power performance area (PPA) yield enhancements are demonstrated for stacked die and chiplet architecture product lines.

Aspects of the present disclosure are directed to a stacked integrated circuit (IC) device including a stiffener die. In some aspects, the stacked IC device includes a first die (e.g., a memory die) that is electrically coupled to a second die (e.g., a memory controller die). The first die includes first active circuitry (e.g., a set of memory cells), and the second die includes second active circuitry that includes a plurality of metal layers. A first metal layer (e.g., Metal 1 layer) of the metal layers is closest to a side of the second die. The second die has reduced thickness that enables via-last formation of one or more conductive vias that extend from the side of the second die to land on the first metal layer (e.g., Metal 1 layer). Conductive vias that land on the first metal layer enable routing of additional signals beyond the first metal layer.

A very thin die can be more susceptible to stress and mechanical forces, which can make the die less able to withstand thermal cycling, handling, or other manufacturing processes. These stresses can cause a bonding interface between the die and neighboring layers to fail, resulting in delamination. Delamination in a stacked IC device can lead to reduced performance, electrical failures, and even complete device failure if interconnections or integrity of the circuit is impacted. The stacked IC device includes a third die (e.g., a stiffener die) that provides mechanical support to the second die (e.g., a relatively thin die) and improves structural integrity of the stacked IC device (e.g., resists delamination and die cracking). The third die can also improve heat conductance from the second die, improving thermal performance of the stacked IC device. To provide the mechanical support to the second die, the third die has a thickness that is larger than a thickness of the second die. The third die may be devoid of active circuitry, but may comprise a plurality of conductive vias to connect (e.g., electrically couple) the metal layers, the conductive vias, or a combination thereof, of the second die to the substrate. For each of the first, second, and third die, the vias may have respective pitches (as explained in more detail below), however, the pitches and the relationship of the pitches should not be understood as an essential element in some aspects of the present disclosure.

### Exemplary Implementations Including a Stacked Integrated Circuit Device Including a Stiffener Die

FIG. 1 illustrates a cross-sectional profile view of a particular implementation of a device 100 (e.g., a stacked IC device, an IC package, or both) that includes a plurality of dies arranged in a stacked configuration. For example, the device 100 includes one or more first dies 120 (e.g., a first die 120A, a first die 120B, and one or more additional first dies), a second die 122, and a third die 124. The second die 122 is positioned between the first die(s) 120 and the third die 124, and may thus be referred to as an intermediate die.

In some examples, a plurality of first dies 120 is included in a dynamic random-access memory (DRAM) stack that forms a 3D-DRAM structure. The first dies 120 (e.g., a DRAM stack or a stacked DRAM die) can correspond to high bandwidth memory (HBM). In some aspects, the first dies 120 are interconnected with conductive vias (e.g., through-silicon vias (TSVs)) and/or hybrid bonding to enable high-density vertical integration and efficient inter-die communication. The stacking of the first dies 120 (e.g., in the 3D-DRAM structure) enables increased memory capacity and bandwidth within a reduced footprint, which is beneficial for applications such as high-performance computing, graphics processing, and neural network acceleration. In some examples, a stack of the first dies 120 can be mounted on a package substrate that is coupled to the second die 122. In some other examples, the stack of first dies 120 can be directly connected to the second die 122. In another example, the stack of first dies 120 (e.g., DRAM stacked die) are stacked with the second die 122 in a 3D stacked arrangement.

In some examples, the second die 122 can correspond to a system-on-chip (SoC). The second die 122 can include an array of compute units, such as a multiply-accumulate (MAC) unit, an arithmetic logic unit (ALU), etc. In a particular aspect, the second die 122 corresponds to a compute die that includes a combination of MAC units, buses, processing elements, a graphic processing unit (GPU), a central processing unit (CPU), a neural processing unit (NPU), a video unit, or an audio unit.

CPUs are typically designed for general-purpose computing and are capable of handling sequential processing, complex logic, and a variety of tasks. A CPU die (e.g., the second die 122) can include a few powerful cores equipped with deep instruction pipelines, large caches, and advanced control mechanisms (e.g., branch prediction and out-of-order execution). CPUs support broad instruction sets (e.g., x86 or ARM) and are well-suited for running operating systems, managing input/output (I/O), and performing tasks involving frequent branching or dynamic control flow.

GPUs are typically designed to handle highly parallel workloads and were originally built for rendering graphics. A GPU die (e.g., the second die 122) can contain hundreds or thousands of smaller, simpler cores arranged to execute the same instruction across many data elements simultaneously, e.g., following a single instruction multiple data (SIMD) or single instruction multiple threads (SIMT) model. GPUs prioritize throughput over low-latency execution and are well-suited for tasks such as 3D rendering, video processing, and compute-heavy operations such as matrix multiplication. GPUs are highly effective when executing data-parallel workloads with regular, predictable patterns.

NPUs are typically designed to accelerate machine learning tasks, particularly neural network inference. An NPU die (e.g., the second die 122) can contain specialized hardware components such as MAC units and tensor processing cores that handle matrix and tensor operations with high efficiency and parallelism. NPUs are often designed to perform low-precision computations (e.g., INT8, FP16), which are common in artificial intelligence (AI) workloads and offer significant performance-per-watt advantages in resource-constrained environments. NPUs are often used in edge devices or mobile applications where power efficiency is key. The control logic in NPUs is streamlined and tailored to execute repetitive, dataflow-intensive tasks characteristic of AI models.

In some aspects, the second die 122 can include I/O physical layer (PHY) circuits, including peripheral component interconnect express (PCIe) PHYs and other interfaces for die-to-die, die-to-cable, or similar high-speed interconnects. The second die 122 can include a memory controller, 3D-DRAM timing control circuits, 3D-DRAM test interfaces, a cache memory (e.g., a static random-access memory (SRAM)), or a combination thereof. The second die 122 can include one or more infrastructure components, such a fuse circuit, a clock generator, a voltage regulator, a debug interface, or a combination thereof.

The stacked configuration of the first die(s) 120, the second die 122, and the third die 124 places the second die 122 in close physical proximity to the first die(s) 120. The reduced distance—such as between the first die(s) 120 (e.g., a DRAM stack) and a processing unit (e.g., an NPU), a control unit (e.g., a memory controller), or both, in the second die 122—enables high speed memory access. As a result, performance is enhanced in memory-intensive applications, such as AI and data center applications.

The second die 122 has a “via last” configuration. For example, a conductive via 156 of the second die 122 extends from a side 184 (e.g., a back) of the second die 122 to a bottom metal layer of a set of metal layers 180 of the second die 122. In this context, the “bottom” metal layer refers to a metal layer of the metal layers 180 that is closest to the side 184 of the second die 122, thus, the bottom metal layer is also referred to herein as a closest active circuitry metal layer of metal layers 180.

The X-axis and Z-axis are indicated in FIG. 1. Y-axis is perpendicular to the X-axis and the Z-axis and extends out of the plane defined by the X-axis and the Z-axis. Each die 120, 122, 124 has two “sides” corresponding to surfaces that are parallel to a plane defined by the X-axis and the Y-axis. For example, the first die 120A has a side 172 (e.g., a “top” surface) and a side 182 (e.g., a “bottom” surface), the second die 122 has a side 174 (e.g., a “top” surface) and a side 184 (e.g., a “bottom” surface), and the third die 124 has a side 176 (e.g., a “top” surface) and a side 186 (e.g., a “bottom” surface). Each die 120, 122, 124 has two “edges” corresponding to surfaces that are parallel to a plane defined by the Y-axis and the Z-axis. For example, the first die 120A has an edge 171 (e.g., a “left” surface) and an edge 181 (e.g., a “right” surface), the second die 122 has an edge 173 (e.g., a “left” surface) and an edge 183 (e.g., a “right” surface), and the third die 124 has an edge 175 (e.g., a “left” surface) and an edge 185 (e.g., a “right” surface). In some aspects, the side 182 of the first die 120A is adjacent to (e.g., facing) the side 174 of the second die 122, and the side 184 of the second die 122 is adjacent to (e.g., facing) the side 176 of the third die 124.

The second die 122 is relatively thin (e.g., thin compared to the first die 120 and the third die 124) and the third die 124 mechanically supports the second die 122 to improve structural integrity of the device 100, for example to resist delamination and fracturing of the device 100. In some examples, the third die 124 also provides improved heat conduction from the second die 122 and thus improves thermal performance of the device 100. In an example, the first die 120A has a first thickness (e.g., between the side 172 and the side 182), the second die 122 has a second thickness (e.g., between the side 174 and the side 184), and the third die 124 has a third thickness (e.g., between the side 176 and the side 186). In a particular aspect, the second thickness (e.g., 3 micron (μm)) is less than the third thickness (e.g., 20 μm). Although the second thickness of the second die 122 in the embodiment illustrated in FIG. 1 is greater than the first thickness of the first die 120A, in some other embodiments the second thickness (e.g., 3 μm) is less than the first thickness (e.g., 15 μm).

Optionally, in some embodiments, the second die 122 and the third die 124 have the same width. In some aspects, the device 100 can be fabricated using wafer-based manufacturing and singulation, resulting in the first die 120, the second die 122, and the third die 124 having uniform width. An advantage of wafer-based manufacturing includes reduced complexity and reduced fabrication cost. In an example, the first die 120A has a first width (e.g., from the edge 171 to the edge 181), the second die 122 has a second width (e.g., from the edge 173 to the edge 183), and the third die 124 has a third width (e.g., from the edge 175 to the edge 185). In some embodiments, the first width is the same as (e.g., equal to) the second width. In some embodiments, the second width is the same as (e.g., equal to) the third width. In a particular aspect, the side 182 has the same dimensions (e.g., the same length and the same width) as the side 174, and the side 176 has the same dimensions (e.g., the same length and the same width) as the side 184. In a particular aspect, each of the side 172, the side 182, the side 174, the side 184, the side 176, and the side 186 has the same dimensions (e.g., the same lengths and the same widths).

Each of the dies 120 and 122 can include integrated circuitry (e.g., active circuitry), such as a plurality of transistors and/or other circuit elements arranged and interconnected to form logic cells, memory cells, etc. In some aspects, “active circuitry” includes components (e.g., transistors) capable of amplifying, controlling, or modifying electrical signals. In contrast, “passive circuitry” includes components (e.g., resistors, capacitors, inductors, etc.) which are not capable of amplifying electrical signals. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, a front end-of-line (FEOL) process may be used to fabricate the integrated circuitry in and/or over the semiconductor substrate.

In an example, a first die 120 includes first active circuitry 142. To illustrate, the first die 120A includes first active circuitry 142A. In an example, the second die 122 includes second active circuitry 152 proximate to a side 174 of the second die 122. In some aspects, a “face” of a die refers to a side of the die that is proximate to active circuitry of the die, and a “back” of the die refers to a side of the die that is opposite the face. For example, the side 174 corresponds to a “face” of the second die 122 and the side 184 corresponds to a “back” of the second die 122. The side 174 of the second die 122 adjacent to the side 182 of the first die 120A corresponds to a “face-up” configuration of the second die 122. In some aspects, the face-up configuration of the second die 122 in the device 100 can result in shorter signal paths between the second active circuitry 152 and the first active circuitry 142A, which may improve data transfer speed and signal integrity.

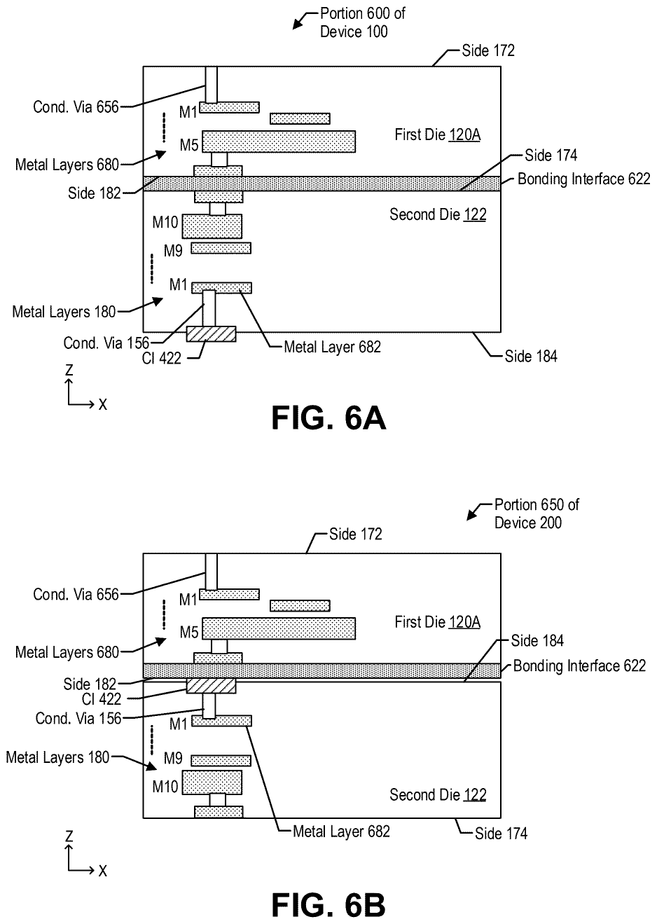

The second active circuitry 152 includes a plurality of metal layers 180. In some aspects, the metal layers (e.g., the metal layers 180) of a die provide a hierarchical network of interconnects, as further described with reference to FIGS. 6A-6B. In an example, lower layers (e.g., metal layer 1 (M1)) correspond to dense short-distance connections, middle layers (e.g., metal layers 2 (M2) and 3(M3 )) facilitate intermediate routing and inter-block communication, and higher layers (e.g., metal layers 4(M4 ) and 5(M5 )) focus on global interconnects, clock distribution, and power delivery.

In some aspects, the first active circuitry 142A defines a set of memory cells. To illustrate, the first die 120A includes a memory die (e.g., a DRAM). In some aspects, the second die 122 includes a memory controller die. To illustrate, the second active circuitry 152 includes memory control circuitry, physical interface circuitry, or a combination thereof. In some aspects, the third die 124 includes a base die. Optionally, in some embodiments, the third die 124 is devoid of active circuitry. In some aspects, the third die 124 may include other circuitry, such as passive circuitry (e.g., capacitors, inductors, resistors).

The dies 120, 122, and 124 may include or correspond to particular IC devices that can be arranged and interconnected as a three-dimensional (3D) IC device. In some implementations, one or more of the dies 120 and 122 include one or more microcontrollers, application specific integrated circuits (ASICs), field programmable gate arrays (FPGAs), CPUs having one or more processing cores, processing systems, SoC, or other circuitry and logic configured to facilitate the operations of the dies 120 and 122. Additionally, or alternatively, one or more of the dies 120 and 122 may include or operate as a memory, such as an SRAM, a DRAM, flash memory, read-only memory (ROM), programmable read-only memory (PROM), erasable programmable read-only memory (EPROM), electrically erasable programmable read-only memory (EEPROM), a solid-state storage device (SSD), or a combination thereof. In a particular aspect, the die 120 is a first chiplet, the die 122 is a second chiplet, the die 124 is a third chiplet, or a combination thereof.

In some implementations, the IC dies are electrically coupled to, or integrated with, respective substrates. For example, the dies 120, 122, and 124 may be electrically coupled (e.g., via one or more contacts or interconnects) to the substrate 102. Any of the conductive interconnects, conductive vias, through-via conductors, and contacts described herein can include, for example, microbumps, conductive pillars, conductive pads (e.g., for pad-to-pad bonding), or other similar chiplet-to-chiplet interconnect contacts used for three-dimensional (3D) chiplet stacking. The second die 122 includes the conductive via 156 that extends from the side 184 to one or more of the metal layers 180. For example, the second die 122 includes the conductive via 156 that extends from the side 184 to a first metal layer of the metal layers 180, and the first metal layer (e.g., M1) is closest to the side 184 among the metal layers 180, as further described with reference to FIG. 6A.

The second die 122 is electrically coupled to the first die 120A. In an example, the first die 120A includes a redistribution layer (RDL) 144A between the first active circuitry 142A and the side 182. In some examples, the RDL 144A corresponds to or includes BEOL interconnect layers. The first die 120A includes a conductive path from the first active circuitry 142A of the first die 120A that passes through the RDL 144A and an RDL 154 of the second die 122 to one or more of the metal layers 180 of the second active circuitry 152 of the second die 122.

The third die 124 is electrically coupled to the second die 122, and electrically couples the second active circuitry 152 of the second die 122 to the substrate 102. In an example, the third die 124 includes a through-via conductor 166 that extends from the side 176 of the third die 124 to the side 186 of the third die 124. The through-via conductor 166 electrically couples the second active circuitry 152 to the substrate 102. For example, the first metal layer (M1) of the metal layers 180 of the second active circuitry 152 is electrically coupled through the conductive via 156 and the through-via conductor 166 to the substrate 102. To illustrate, a conductive path from the first metal layer (M1) of the metal layers 180 of the second active circuitry 152 passes through the conductive via 156 and the through-via conductor 166 to the substrate 102. In some aspects, the through-via conductor 166 is aligned with the conductive via 156. In some aspects, a characteristic dimension of the through-via conductor 166 is greater than a corresponding characteristic dimension of the conductive via 156. In some examples, a characteristic dimension includes a height, a width, a thickness, or a combination thereof. A single conductive via 156 of the second die 122 aligned with a single through-via conductor 166 of the third die 124 is provided as an illustrative example; in other examples the second die 122 can include a set of multiple conductive vias 156 that is aligned with a through-via conductor 166 of the third die 124. To illustrate, the second die 122 has a characteristic dimension (e.g., a 3 μm thickness) that is less than a corresponding characteristic dimension (e.g., a 20 μm thickness) of the third die 124. In some examples, a via pitch of a conductive via 156 of the second die 122 (e.g., having the lower die thickness) can be less than a via pitch of a through-via conductor 166 of the third die 124 (e.g., having the greater die thickness). In some aspects, a first conductive path passes through a first conductive via 156 of the set and a through-via conductor 166 of the third die 124, and a second conductive path passes through a second conductive via 156 of the set and the same through-via conductor 166.

In some aspects, a first plurality of conductive vias of a first die 120 has a pitch 121, a second plurality of conductive vias (e.g., the set of conductive vias 156) of the second die 122 has a pitch 157, and a third plurality of conductive vias (e.g., the through-via conductors 166) of the third die 124 has a pitch 167. In a particular aspect, the pitch 121 corresponds to a distance between a pair of conductive vias of the first die 120 that are closest to each other among the first plurality of conductive vias. In a particular aspect, the pitch 157 corresponds to a distance between a pair of conductive vias of the second die 122 that are closest to each other among the second plurality of conductive vias. In a particular aspect, the pitch 167 corresponds to a distance between a pair of conductive vias of the third die 124 that are closest to each other among the third plurality of conductive vias. In a particular aspect, the pitch 157 is 2 to 30 times greater than the pitch 121, the pitch 167 is 2 to 30 times greater than the pitch 121, or both. In an example, the pitch 121 is in a range from 1 to 3 micron (e.g., 2 micron), the pitch 157 is in a range from 5 to 50 microns, and the pitch 167 is in a range from 5 to 50 microns.

In some examples, a distance between a first conductive via and a second conductive via corresponds to a distance between a center of the first conductive via and a center of the second conductive via. For example, the pitch 157 corresponds to a distance between an axis of symmetry (depicted with a dashed line) of a first conductive via 156 and an axis of symmetry (depicted with a dashed line) of a second conductive via 156 of the second die 122. Each of the pitch 157 and the pitch 167 is greater than the pitch 121. In some examples, the pitch 157 is equal to the pitch 167. In some other examples, the pitch 167 is greater than the pitch 157. In yet other examples, the pitch 157 is greater than the pitch 167.

In some aspects, an RDL of a die enables redistribution, routing, and managing input/output and power connections. The first die 120 includes an RDL 144 that is electrically coupled to the first active circuitry 142. For example, the first die 120A includes an RDL 144A that is electrically coupled to the first active circuitry 142A. The second die 122 includes an RDL 154 that is electrically coupled to the metal layers 180 of the second active circuitry 152. In some aspects, the side 174 of the second die 122 is adjacent to a side of the first die 120A, and the RDL 154 is disposed between the side 182 of the first die 120A and the metal layers 180 of the second active circuitry 152 of the second die 122.

It should be understood that the device 100 may include additional components, other components, fewer components, or a combination thereof, to support the functionality described herein. As non-limiting examples, the device 100 may include additional IC devices, additional layers, additional dies, additional packages, additional interconnects, additional structures, other components, different components, or a combination thereof, to support the functionality and technical advantages disclosed herein.

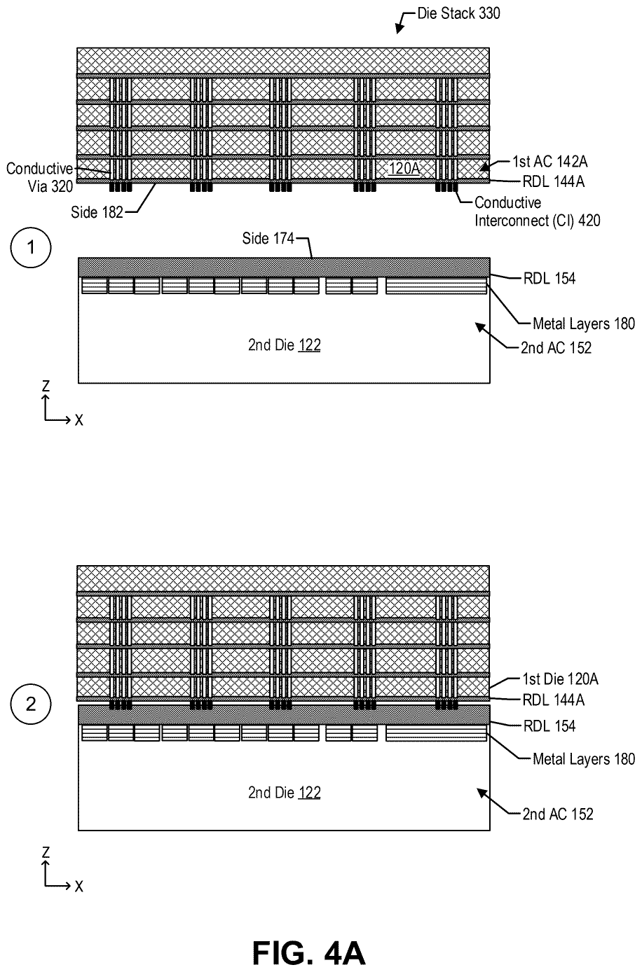

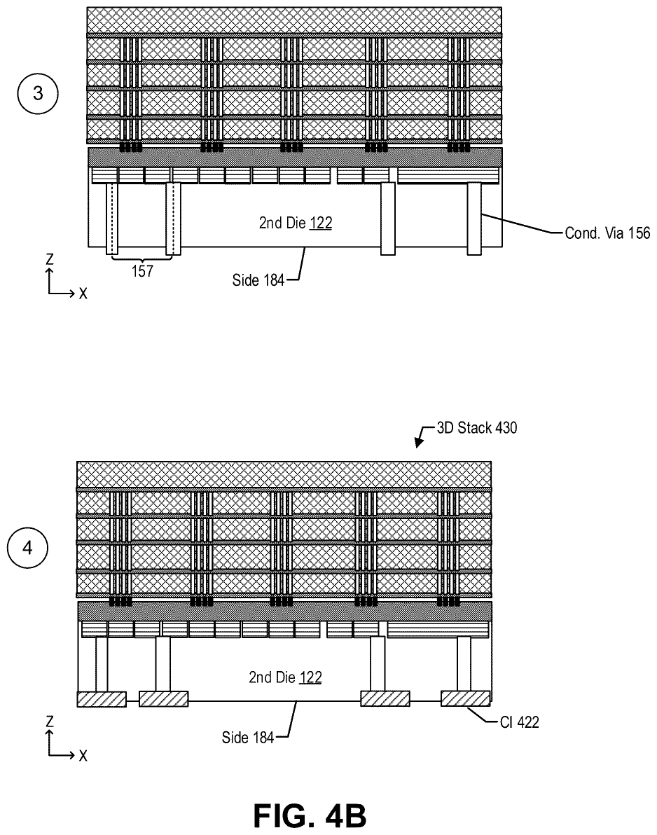

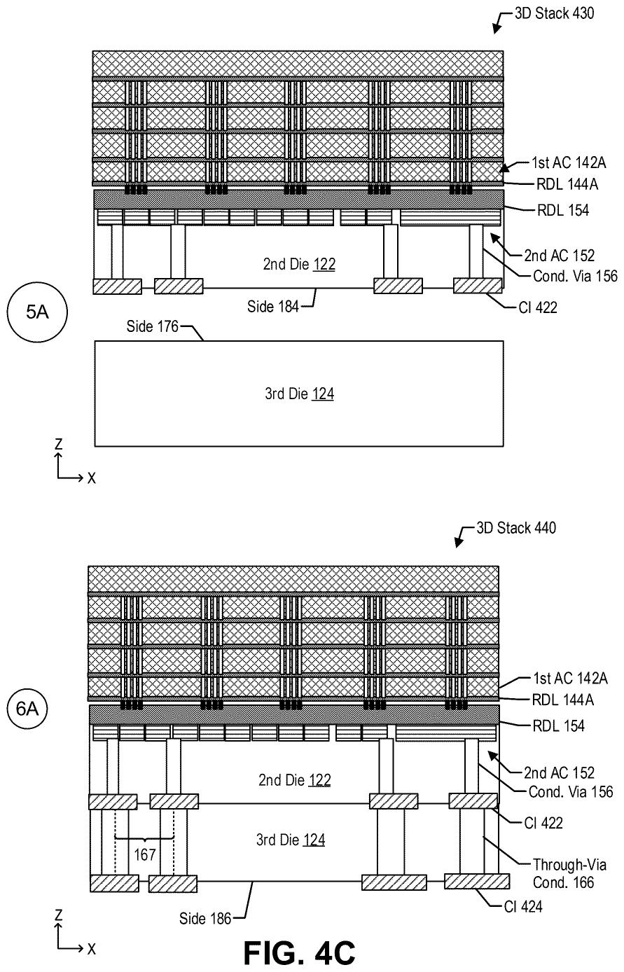

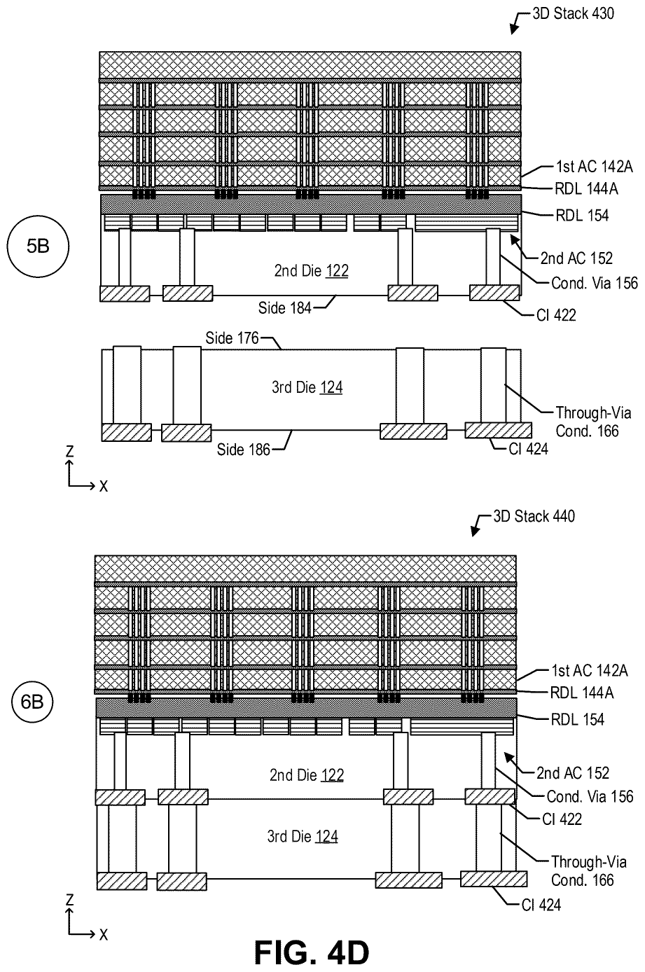

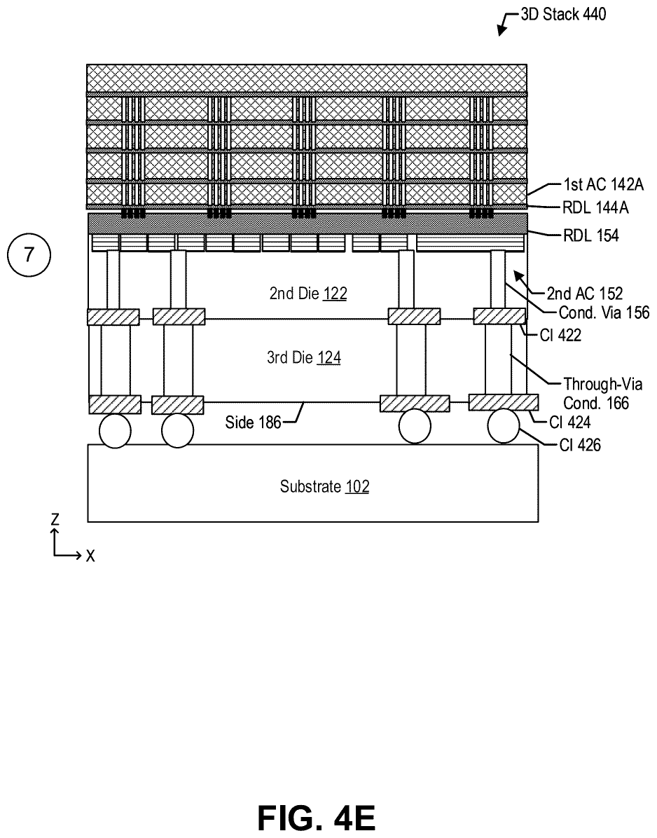

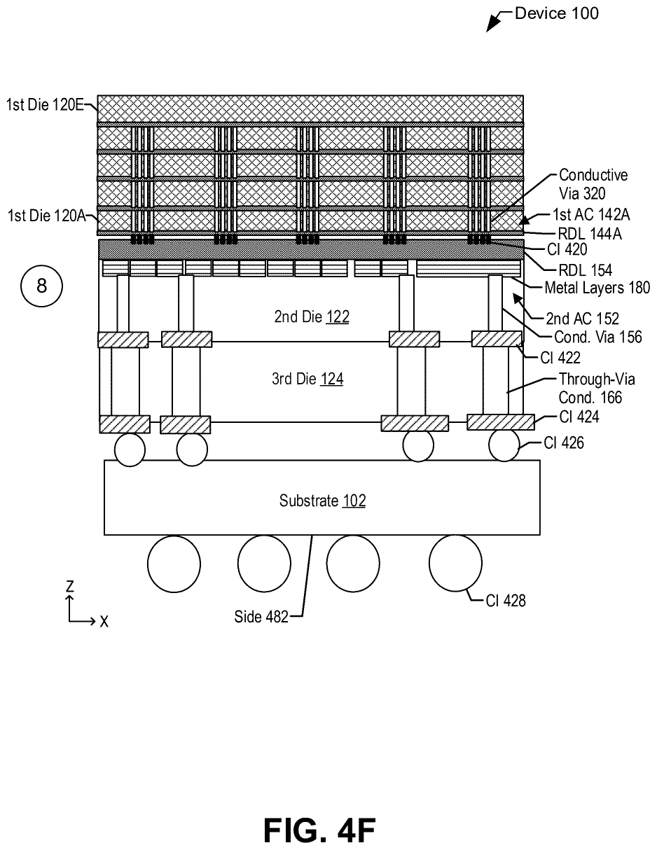

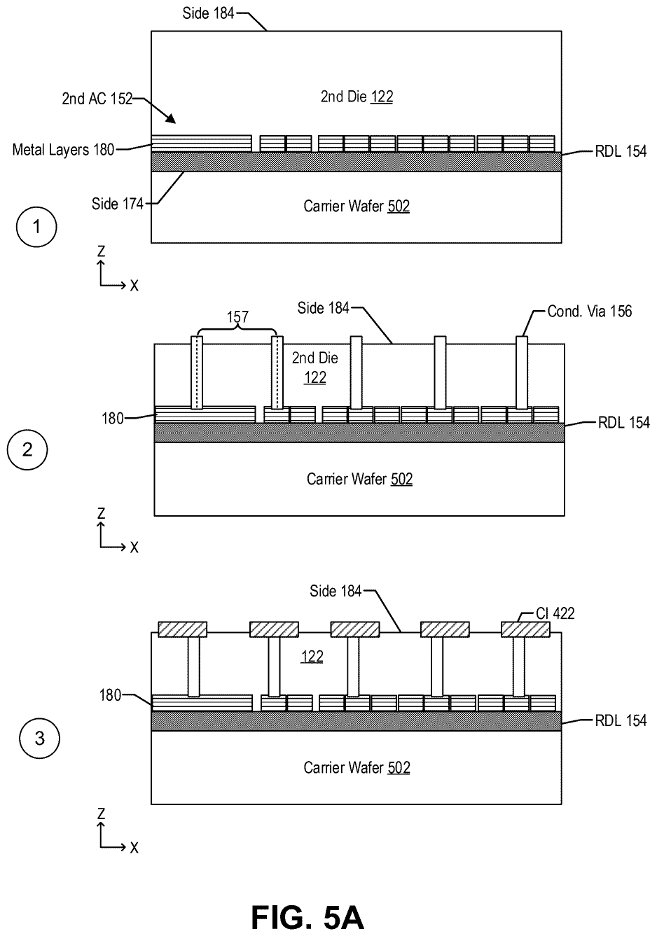

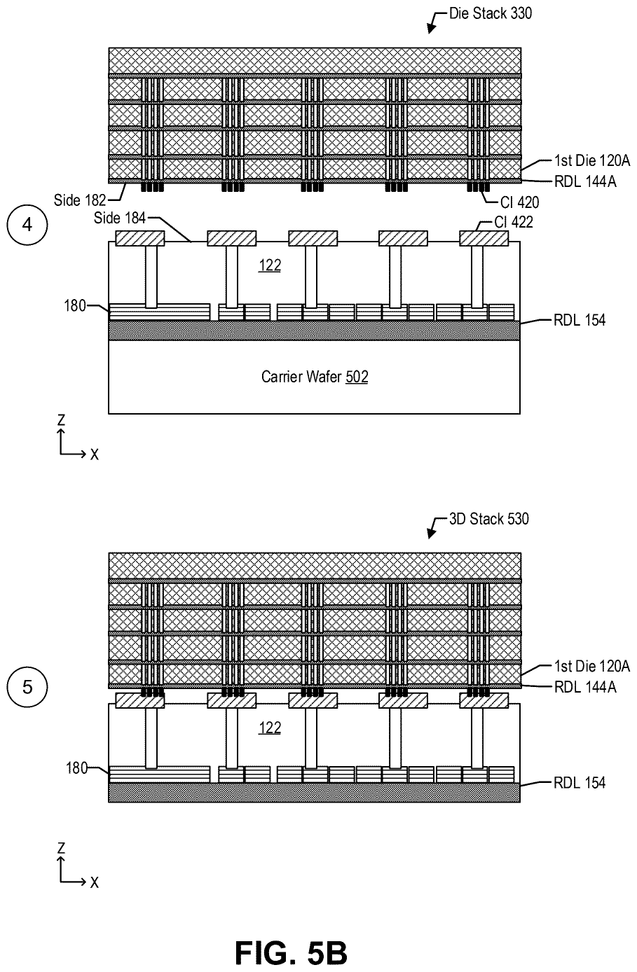

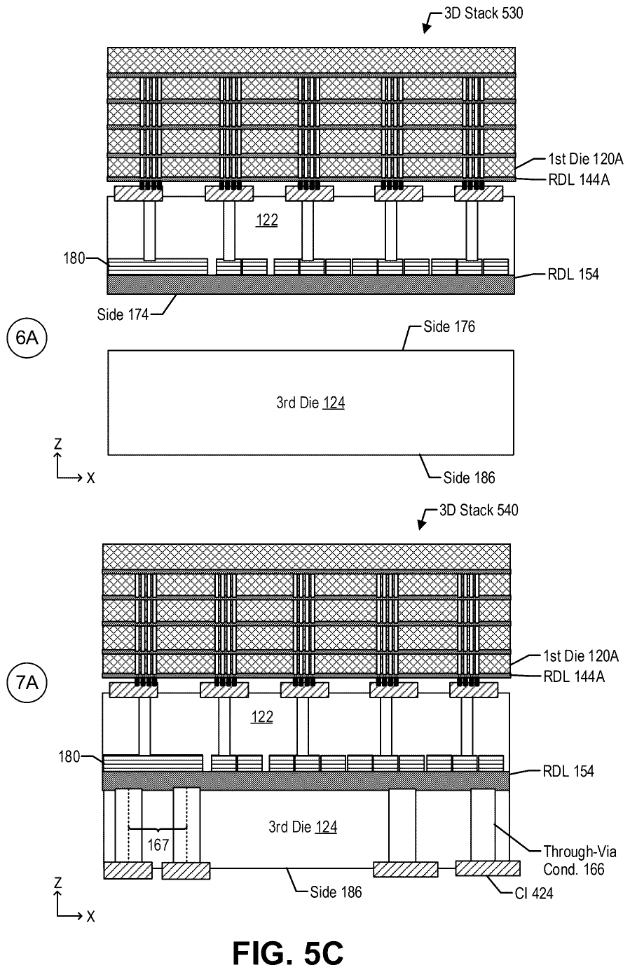

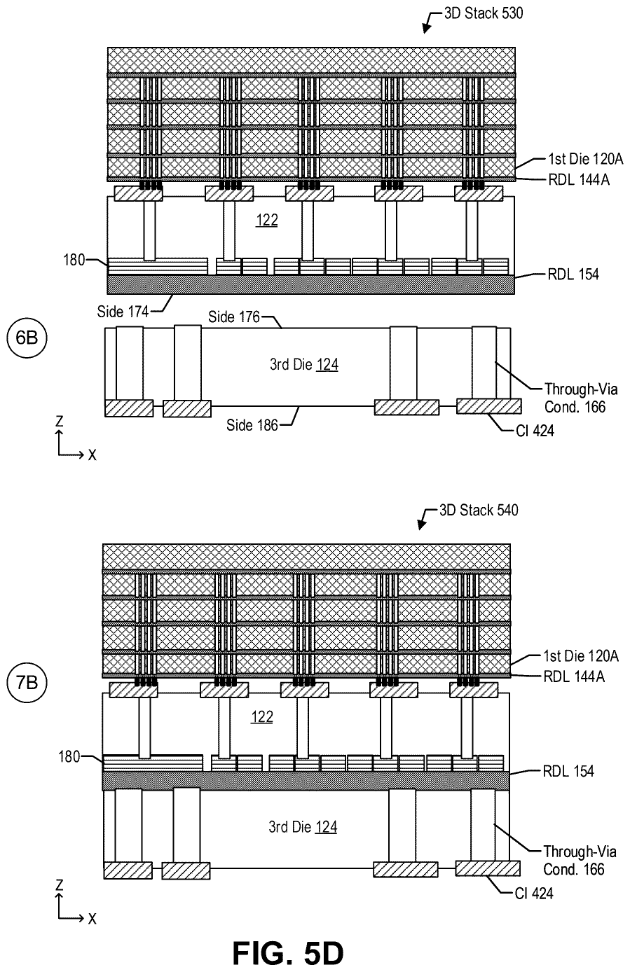

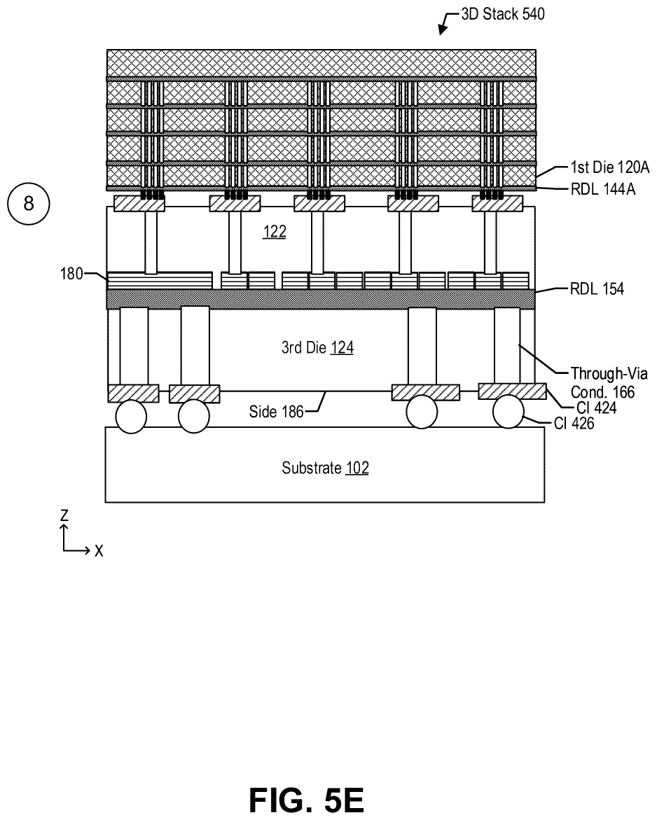

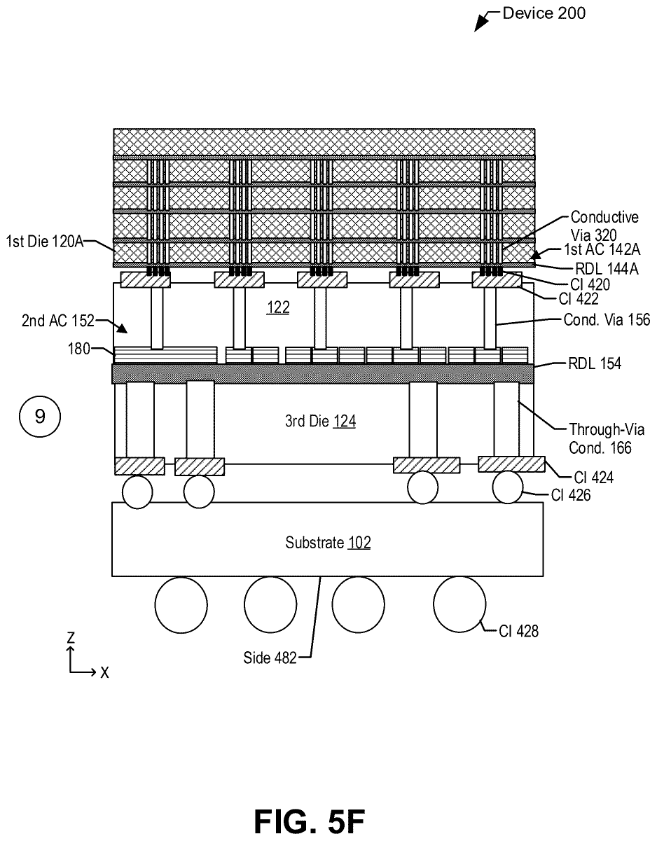

In some embodiments, “via-last” fabrication techniques can be used to form the second die 122. A via-last fabrication technique can include formation of the conductive vias 156 subsequent to formation of the metal layers 180 and the RDL 154 of the second die 122, as further described with reference to FIGS. 4B and 5A. Via-last fabrication improves yield because the conductive vias 156 are added to the second die 122 that is a known good die (KGD). Material of the conductive vias 156 that are added last does not have to withstand high temperatures typically associated with front-end processing. Hence, in some examples, temperature-sensitive low-k dielectric layers and advanced interconnects can be included in the conductive vias 156. Using via-last fabrication techniques enables the second die 122 to be coupled to the substrate 102 and the first die(s) 120 via short, generally direct, conductive paths, which provides improved signal integrity and better power delivery network (PDN) performance. However, via-last fabrication techniques involve forming openings from the back of the die (e.g., the side 184 of the second die 122) to the bottom metal layer of the metal layers 180. The bottom metal layer is generally the thinnest of the metal layers 180. When forming an opening from the back of the die, it can be difficult to detect that the opening has reached the bottom metal layer. As a result, it is easy to overshoot the bottom metal layer, which can render the die inoperative, thereby increasing cost and decreasing production yield.

One way to reduce the likelihood of overshooting the bottom metal layer is to reduce the depth of the opening being formed, such as by thinning the second die 122. However, in a stacked configuration, such as in the device 100, thinning the second die 122 reduces the structural integrity of the second die 122 and of the die stack. These challenges are addressed in the device 100 by making the second die 122 thin enough to enable reliable use of via-last fabrication techniques and coupling the second die 122 to the third die 124 so that the third die 124 can provide structural reinforcement for the second die 122 and the stack. The device 100 thus has improved routing by enabling the conductive via 156 to land on the first metal layer (e.g., M1) of the metal layers 180 of the relatively thin second die 122, while the third die 124 provides mechanical support to the second die 122. A technical advantage of the third die 124 providing mechanical support to the second die 122 includes retaining structural integrity of the device 100, e.g., to resist delamination and fracturing of the device 100. In some examples, the third die 124 also provides improved heat conduction from the second die 122 and thus improves thermal performance of the device 100. The face-up configuration of the second die 122 can also result in improved data transfer speed and signal integrity.

In a particular implementation, the device 100 (e.g., a stacked IC device) includes a first die (e.g., the first die 120A) that includes first active circuitry (e.g., the first active circuitry 142A) that defines a set of memory cells. The device 100 includes a second die (e.g., the second die 122) electrically coupled to the first die. The second die includes second active circuitry (e.g., the second active circuitry 152) proximate to a first side (e.g., the side 174) of the second die. The second active circuitry includes a plurality of metal layers (e.g., the metal layers 180). The second die includes a conductive via (e.g., the conductive via 156) that extends from a second side (e.g., the side 184) of the second die to a first metal layer (e.g., M1) of the plurality of metal layers. The first metal layer is closest among the plurality of metal layers to the second side of the second die. The device 100 includes a third die (e.g., the third die 124) electrically coupled to the second die. The third die includes a through-via conductor (e.g., the through-via conductor 166) to electrically couple the second active circuitry to a substrate (e.g., the substrate 102). The second die is disposed between the first die and the third die.

In a particular implementation, the first die includes a memory die (e.g., the first die 120A), the second die includes a memory controller die (e.g., the second die 122), and the third die includes a base die (e.g., the third die 124). In a particular implementation, the conductive via (e.g., the conductive via 156) is aligned with the through-via conductor (e.g., the through-via conductor 166). In a particular implementation, the device 100 includes a conductive path from the first metal layer (e.g., M1) through the conductive via (e.g., the conductive via 156) and the through-via conductor (e.g., the through-via conductor 166) to the substrate (e.g., the substrate 102).

In a particular implementation, the third die (e.g., the third die 124) is devoid of active circuitry. In a particular implementation, a thickness (e.g., the second thickness between the side 174 and the side 184) of the second die (e.g., the second die 122) is less than a thickness (e.g., the first thickness between the side 172 and the side 182) of the first die (e.g., the first die 120A) and less than a thickness (e.g., the third thickness between the side 176 and the side 186) of the third die (e.g., the third die 124).

In a particular implementation, a characteristic dimension of the through-via conductor (e.g., the through-via conductor 166) is greater than a corresponding characteristic dimension of the conductive via (e.g., the conductive via 156).

In a particular implementation, the second die and the third die have a same width. For example, the second width between the edge 173 and the edge 183 is the same as the third width between the edge 175 and the edge 185. In a particular implementation, the first die, the second die, and the third die have a same width. For example, the first width between the edge 171 and the edge 181, the second width between the edge 173 and the edge 183, and the third width between the edge 175 and the edge 185 are the same.

In a particular implementation, the first side (e.g., the side 174) of the second die (e.g., the second die 122) is adjacent to a first side (e.g., the side 182) of the first die (e.g., the first die 120A). In a particular implementation, the second die (e.g., the second die 122) includes an RDL (e.g., the RDL 154). The RDL is disposed between the first die (e.g., the first die 120A) and the second active circuitry (e.g., the second active circuitry 152) of the second die (e.g., the second die 122).

In a particular implementation, the second active circuitry (e.g., the second active circuitry 152) includes memory control circuitry. In a particular implementation, the second active circuitry (e.g., the second active circuitry 152) includes physical interface circuitry. In a particular implementation, the third die (e.g., the third die 124) mechanically supports the second die (e.g., the second die 122) to resist delamination.

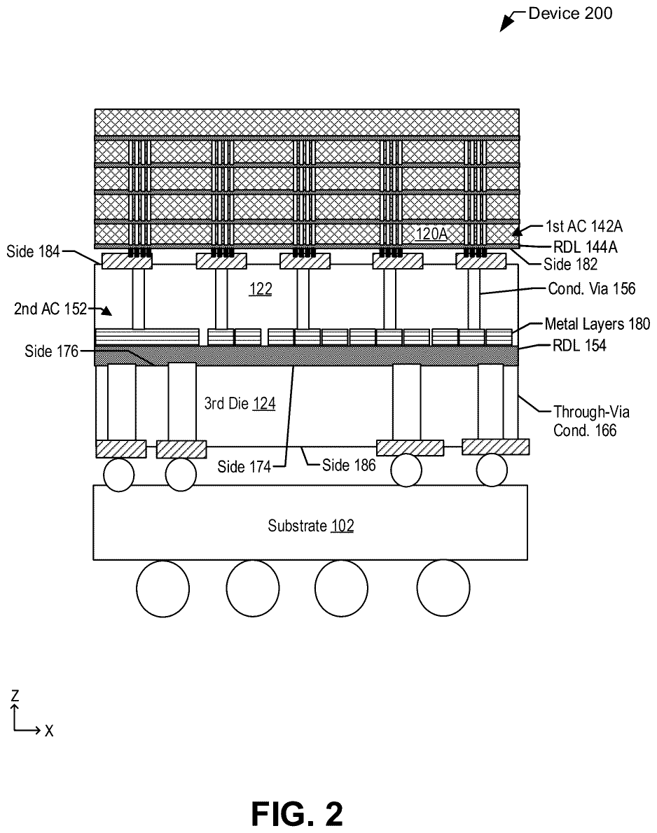

FIG. 2 illustrates a cross-sectional profile view of a particular implementation of a device 200 (e.g., a stacked IC device) that includes a plurality of dies arranged in a stacked configuration. For example, the device 200 includes the one or more first dies 120, the second die 122, and the third die 124 (e.g., the stiffener die).

The device 200 of FIG. 2 includes many of the same components and features as are described above with reference to FIG. 1. Such components and features are physically and operationally the same as described above with reference to FIG. 1 and are labeled in FIG. 2 using the same reference numbers. In some implementations, the device 200 includes some of the same features and components as the device 100 of FIG. 1; however, some components and features illustrated in FIG. 1 have been omitted from (or are not labeled with reference numbers in) FIG. 2 for simplicity of illustration and to highlight differences between the device 100 and the device 200. Omission of such features and reference numbers should not be understood as limiting the features and components of FIG. 2 to only those specifically called out below. For example, while FIG. 2 does not include the reference number 120B of FIG. 1, the device 200 can include the first die 120B.

In the example shown in FIG. 2, the device 200 includes the second die 122 in a “face-down” configuration. For example, the second die 122 is disposed between the first die 120A and the third die 124, with the side 174 (e.g., the face) of the second die 122 adjacent to (e.g., facing) the side 176 of the third die 124 and the side 184 of the second die 122 is adjacent to (e.g., facing) the side 182 of the first die 120A. The RDL 154 of the second die 122 is between the metal layers 180 of the second active circuitry 152 and the side 176 of the third die 124. In some aspects, the face-down configuration of the second die 122 in the device 200 can result in reduced thermal interference from the second active circuitry 152 that could impact performance of the first active circuitry 142A.

The second die 122 is electrically coupled to the first die 120A. For example, a conductive path from the first active circuitry 142A of the first die 120A passes through the RDL 144A and the conductive via 156 to the first metal layer (M1) of the metal layers 180 of the second active circuitry 152 of the second die 122. The third die 124 is electrically coupled to the second die 122, and electrically couples the second active circuitry 152 of the second die 122 to the substrate 102. For example, a conductive path from the metal layers 180 of the second active circuitry 152 of the second die 122 passes through the RDL 154 and through the through-via conductor 166 of the third die 124 to the substrate 102.

In a particular implementation, the first side (e.g., the side 174) of the second die (e.g., the second die 122) is adjacent to a first side (e.g., the side 176) of the third die (e.g., the third die 124). In a particular implementation, the second die (e.g., the second die 122) includes an RDL (e.g., the RDL 154). The RDL (e.g., the RDL 154) is disposed between the third die (e.g., the third die 124) and the second active circuitry (e.g., the second active circuitry 152) of the second die (e.g., the second die 122).

The second die 122 of the device 200 is thin enough to enable reliable use of via-last fabrication techniques and the second die 122 is coupled to the third die 124 so that the third die 124 can provide structural reinforcement for the second die 122 and the stack. The device 200 thus has improved routing by enabling the conductive via 156 to land on the first metal layer (e.g., M1) of the metal layers 180 of the relatively thin second die 122, while the third die 124 provides mechanical support to the second die 122. A technical advantage of the third die 124 providing mechanical support to the second die 122 includes retaining structural integrity of the device 200, e.g., to resist delamination and fracturing of the device 200. In some examples, the third die 124 also provides improved heat conduction from the second die 122 and thus improves thermal performance of the device 200. The face-down configuration of the second die 122 can also result in improved thermal management.

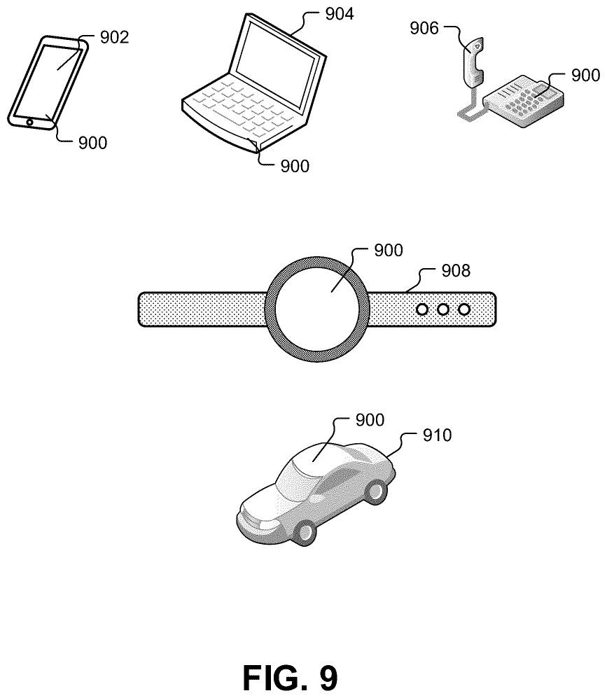

While FIGS. 1 and 2 illustrate example devices that include the first die 120A, the second die 122, and the third die 124, in other examples, one or more additional integrated devices, packages, or some combination thereof can be present in a stacked integrated circuit without departing from the scope of the subject disclosure. Further, the first die 120A, the second die 122, and the third die 124 of FIG. 2 can be integrated with or included within a wide variety of other devices. For example, a device that includes one or more of the first die 120A, the second die 122, and the third die 124 disclosed herein can include components such as a power management integrated circuit (PMIC), an application processor, a modem, a radio frequency (RF) device, a passive device, a filter, a capacitor, an inductor, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. In such devices, the first die 120A and the second die 122 can operate as any of these components (or a combination of these components) that includes active circuitry. In some implementations, the device 100, the device 200, or both, can be integrated in a smartphone, a tablet computer, a fixed location terminal device, an automobile, a wearable electronic device, a laptop computer, or some combination thereof, as described in more detail below with reference to FIG. 9.

### Exemplary Sequences for Fabricating a Stacked IC Device Including a Stiffener Die

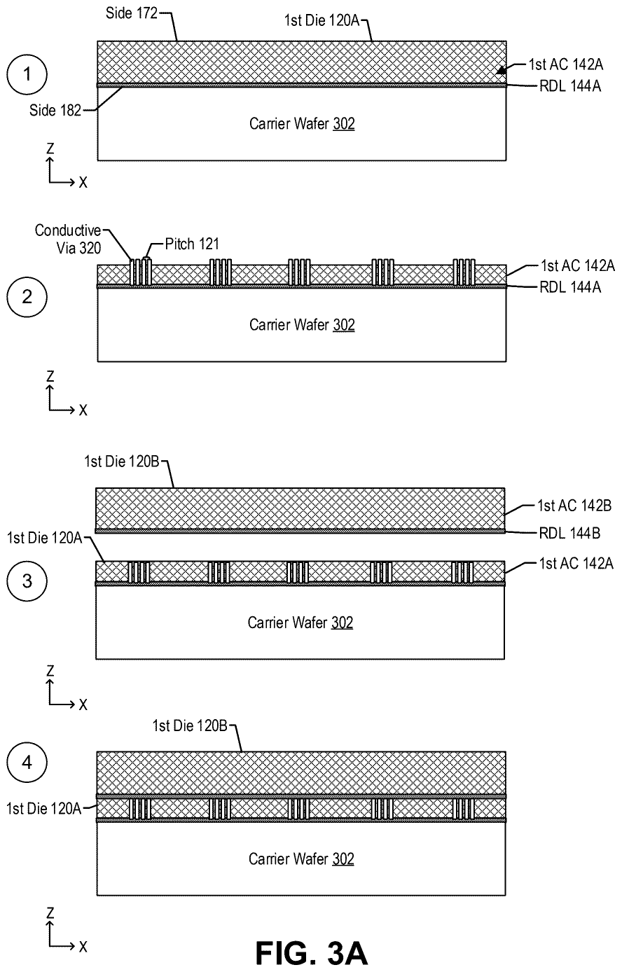

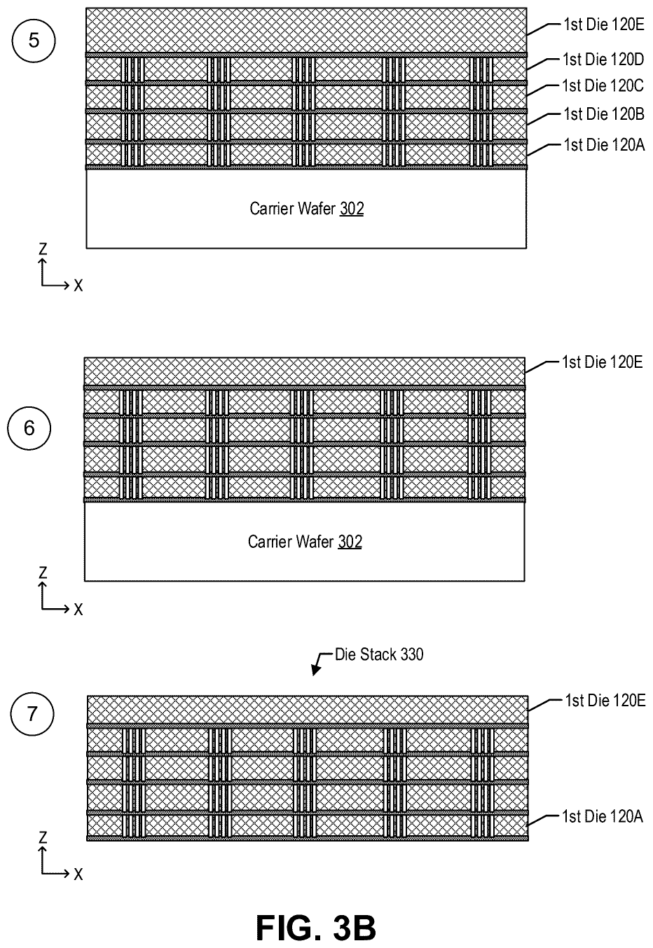

In some implementations, fabricating a stacked IC device includes several processes. FIGS. 3A-3B illustrate an exemplary sequence for fabricating or providing a die stack that includes a plurality of the first dies 120.

FIGS. 4A-4F illustrate an exemplary sequence for fabricating or providing a device that includes a conductive via 156 in a second die 122 (e.g., an intermediate die) that extends from a side 184 of the second die 122 to a closest active circuitry metal layer of the metal layers 180 of the second die 122, as described with reference to FIG. 1. In some embodiments, the device includes a die stack, e.g., the die stack fabricated using the exemplary sequence of FIGS. 3A-3B. In some implementations, the sequence of FIGS. 4A-4F may be used to provide (e.g., during fabrication of) the device 100 of FIG. 1.

FIGS. 5A-5F illustrate an exemplary sequence for fabricating or providing a device that includes a conductive via 156 in a second die 122 (e.g., an intermediate die) that extends from a side 184 of the second die 122 to a closest active circuitry metal layer of the metal layers 180 of the second die 122, as described with reference to FIG. 2. In some embodiments, the device includes a die stack, e.g., the die stack fabricated using the exemplary sequence of FIGS. 3A-3B. In some implementations, the sequence of FIGS. 5A-5F may be used to provide (e.g., during fabrication of) the device 200 of FIG. 2.

It should be noted that the sequence of FIGS. 3A-3B, the sequence of FIGS. 4A-4F, or the sequence of FIGS. 5A-5F may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 3A-3B, 4A-4F, and 5A-5F.

Each of the various stages of the sequence illustrated in FIGS. 3A-3B shows a single die stack being formed. In other implementations, a plurality of die stacks can be formed concurrently. For example, while the description of FIGS. 3A and 3B refer to a first die 120A, the operations described can be performed using wafer-level operations, panel-level operations, or strip-level operations rather than using individual package-level operations. To illustrate, the first die 120A of FIGS. 3A and 3B can be one die among a plurality of dies formed on or defined by a first wafer.

Stage 1 of FIG. 3A illustrates a state after obtaining a first die 120A attached to a carrier wafer 302. For example, as part of Stage 1, the first die 120A may be placed to attach the side 182 to the carrier wafer 302. The first die 120A can be attached to the carrier wafer 302 using various attachment techniques. For example, in some aspects, an adhesive layer is applied to the carrier wafer 302 and the side 182 of the first die 120A is placed on the adhesive layer. In some other aspects, a removable tape is applied to the carrier wafer 302 and the side 182 of the first die 120A is placed on the tape. In yet some other aspects, vacuum or mechanical clamps may be used to hold the first die 120A in place on the carrier wafer 302.

Stage 2 illustrates a state after thinning the first die 120A and forming one or more conductive vias 320 through the first die 120A. For example, as part of Stage 2, the first die 120A is thinned to a target first thickness (e.g., 15 μm) between the side 172 and the side 182 and the one or more conductive vias 320 are formed in the first die 120A that extend from the side 172 to the side 182. After thinning of the first die 120A, via-last fabrication techniques are used to create the one or more conductive vias 320 in the first die 120A. For example, openings are formed in the first die 120A from the side 172, sidewalls of the openings are insulated, and metallization operations are used to fill or line the openings to form conductive vias 320. In some examples, the openings can be formed using laser drilling or etching processes. In some examples, the sidewalls of the openings can be insulated by depositing a thin dielectric layer using thermal oxidation or chemical vapor deposition. In some examples, the metallization operations can include filling or lining the openings with a metal (e.g., copper) using electroplating or chemical vapor deposition.

The conductive vias 320 have the pitch 121. For example, the pitch 121 corresponds to a distance between two of the conductive vias 320 that are closest to each other (e.g., have the shortest distance to each other) among the conductive vias 320. In a particular aspect, the distance is measured from a center (e.g., an axis of symmetry) of a first conductive via 320 to a center (e.g., an axis of symmetry) of a second conductive via 320.

Stage 3 illustrates a state after planarization of the one or more conductive vias 320 and alignment of a first die 120B with the first die 120A. For example, as part of Stage 3, chemical mechanical polishing can be used to planarize a surface of the first die 120A including the one or more conductive vias 320. The first die 120B is aligned with the first die 120A with the RDL 144B facing the first die 120A.

Stage 4 illustrates a state after attachment of the first die 120B to the first die 120A. For example, as part of Stage 4, various techniques of die bonding can be used to attach the first die 120B to the first die 120A. In some aspects, an adhesive material is applied to the first die 120A, the first die 120B is placed (e.g., pressed) on the adhesive material, and the adhesive material is cured using heat or ultraviolet light. In some aspects, conductive interconnects (e.g., microbumps or solder balls) are deposited on contact pads of the side 172 of the first die 120A or a side of the first die 120B, the first die 120B is placed on the first die 120, and the die stack undergoes reflow to melt the conductive interconnects (e.g., solder) to form electrical and mechanical connections.

Stage 5 of FIG. 3B illustrates a state after multiple iterations of Stages 2-4 of FIG. 3A to obtain a stack of multiple first dies 120. For example, as part of Stage 5, the first die 120B is thinned, one or more conductive vias are formed through the first die 120B that are aligned with the one or more conductive vias 320 of the first die 120A, the one or more conductive vias of the first die 120B are planarized, a first die 120C is aligned with the first die 120B, and the first die 120C is attached to the first die 120B. Similarly, the first die 120D is attached to the first die 120C, and the first die 120E is attached to the first die 120D. It should be understood that the first dies 120 including five dies is provided as an illustrative example; in other examples the first dies 120 can include fewer than five or more than five dies.

Stage 6 illustrates a state after thinning a last attached first die 120 (e.g., the first die 120E). For example, as part of Stage 6, the first die 120E is thinned to a target thickness (e.g., 15 μm).

Stage 7 illustrates a state after removal of the carrier wafer 302. For example, as part of Stage 7, an attachment mechanism (e.g., an adhesive, tape, vacuum, or clamp) is removed to detach the carrier wafer 302.

Formation of a die stack 330 is complete after Stage 7 of FIG. 3B. In some implementations, the die stack 330 can be used to form the device 100, as further described with reference to FIGS. 4A-4F, or the device 200, as further described with reference to FIGS. 5A-5F.

Although certain Stages are illustrated in FIGS. 3A-3B in forming the die stack 330, other processes can be included in the fabrication of the die stack 330 without departing from the scope of the subject disclosure. For example, fabricating the die stack 330 can include using a first die 120 that includes conductive vias formed prior to attachment to the carrier wafer 302 or to another first die 120.

Each of the various stages of the sequence illustrated in FIGS. 4A-4F shows a single stacked IC device being formed. In other implementations, a plurality of IC devices can be formed concurrently. For example, while the description of FIGS. 4A-4F refer to a second die 122 and a third die 124, the operations described can be performed using wafer-level operations, panel-level operations, or strip-level operations rather than using individual package-level operations. To illustrate, the second die 122 of FIGS. 4A-4F can be one die among a plurality of dies formed on or defined by a second wafer, and the third die 124 of FIGS. 4C-4F can be one die among a plurality of dies formed on or defined by a third wafer.

Stage 1 of FIG. 4A illustrates a state after forming one or more conductive interconnects (CIs) 420 on the first die 120A of the die stack 330 and aligning the die stack 330 with the second die 122. For example, as part of Stage 1, the one or more conductive interconnects 420 are formed on the side 182 of the first die 120A in alignment with the one or more conductive vias 320 of the first die 120. In some examples, metal deposition and patterning (e.g., etching) are used to form the one or more conductive interconnects 420. In some examples, metal pads are formed on the side 182 of the first die 120A in alignment with the one or more conductive vias 320 of the first die 120, and solder bumps are placed on the metal pads and the die stack 330 undergoes reflow to melt the solder to form electrical and mechanical connections with the RDL 144A. After forming the one or more conductive interconnects 420, the die stack 330 is aligned with the side 182 of the first die 120A facing the side 174 of the second die 122. The second die 122 includes the RDL 154 between the side 174 and the metal layers 180 of the second active circuitry 152.

Stage 2 illustrates a state after attachment of the one or more conductive interconnects 420 on the side 182 of the first die 120A to the RDL 154 of the second die 122. For example, as part of Stage 2, the one or more conductive interconnects 420 of the die stack 330 are placed on the side 174 of the second die 122, Various attachment techniques can be used to attach the one or more conductive interconnects 420 of the die stack 330 to the RDL 154 of the second die 122. For example, reflow is performed to melt the solder of the one or more conductive interconnects 420 to form electrical and mechanical connections with the RDL 154.

Stage 3 of FIG. 4B illustrates a state after thinning of the second die 122 and formation of one or more conductive vias 156 that extend from the side 184 of the second die 122 to a first metal layer (e.g., M1) of the metal layers 180 that is closest to the side 184 among the metal layers 180. For example, as part of Stage 3, the second die 122 is thinned to a target second thickness (e.g., 3 μm). To illustrate, in some aspects, attaching the second die 122 to the one or more first dies 120 provides structural support that enables thinning of the second die 122 to reliably use via-last fabrication techniques, e.g., without overshooting the bottom metal layer. After thinning the second die 122, via-last fabrication techniques are used to create the one or more conductive vias 156 in the second die 122. For example, openings are formed in the second die 122 from the side 184, sidewalls of the openings are insulated, and metallization operations are used to fill or line the openings to form conductive vias 156. In some examples, the openings can be formed using laser drilling or etching processes. In some examples, the sidewalls of the openings can be insulated by depositing a thin dielectric layer using thermal oxidation or chemical vapor deposition. In some examples, the metallization operations can include filling or lining the openings with a metal (e.g., copper) using electroplating or chemical vapor deposition.

The conductive vias 156 have the pitch 157. For example, the pitch 157 corresponds to a distance between two of the conductive vias 156 that are closest to each other (e.g., have the shortest distance to each other) among the conductive vias 156. In a particular aspect, the distance is measured from a center (e.g., an axis of symmetry) of a first conductive via 156 to a center (e.g., an axis of symmetry) of a second conductive via 156.

Stage 4 illustrates a state after planarization of the one or more conductive vias 156 and formation of one or more conductive interconnects 422 that are aligned with the one or more conductive vias 156. For example, as part of Stage 4, chemical mechanical polishing can be used to planarize a surface of the second die 122 including the one or more conductive vias 156. In some examples, metal deposition and patterning (e.g., etching) is used to form the one or more conductive interconnects 422. In some examples, metal pads are formed on the side 184 of the second die 122 in alignment with the one or more conductive vias 156 of the second die 122, and solder bumps are placed on the metal pads and reflow is performed to melt the solder to form electrical and mechanical connections with the one or more conductive vias 156. Formation of a three-dimensional (3D) stack 430 is complete after Stage 4 of FIG. 4B.

It should be understood that a conductive interconnect 422 formed in contact with a single conductive via 156 is provided as an illustrative example; in other examples a conductive interconnect 422 is formed in contact with a set of multiple conductive vias 156 of the second die 122.

Stage 3 of FIG. 4B includes via-last formation of the one or more conductive vias 156 subsequent to attachment of the second die 122 to the die stack 330. In some other implementations, the second die 122 is obtained that includes the one or more conductive vias 156, as further described with reference to Stages 1-3 of FIG. 5A, prior to Stage 1 of FIG. 4A. For example, the second die 122 is attached to a carrier wafer, the second die 122 is thinned, the one or more conductive vias 156 are formed to extend from the side 184 to land on the first metal layer (e.g., M1 layer), the one or more conductive vias 156 are planarized, and the one or more conductive interconnects 422 are formed on the one or more conductive vias 156. The RDL 154 is attached to the one or more conductive interconnects 420, as described with reference to Stages 1 and 2 of FIG. 4A, and the carrier wafer is removed. In these implementations, Stages 3 and 4 of FIG. 4B can be skipped.

Stage 5A of FIG. 4C illustrates a state after alignment of the 3D stack 430 with the third die 124. For example, as part of Stage 5A, the 3D stack 430 is aligned with the third die 124 such that the one or more conductive interconnects 422 on the side 184 of the second die 122 are facing the side 176 of the third die 124. In some aspects, the third die 124 is devoid of active circuitry. In some aspects, the third die 124 may include other circuitry, such as passive circuitry (e.g., capacitors, inductors, resistors).

Stage 6A illustrates a state after attachment of the one or more conductive interconnects 422 of the 3D stack 430 to the third die 124, formation of one or more through-via conductors 166 that extend through the third die 124, and formation of one or more conductive interconnects 424 that are aligned with the one or more through-via conductors 166. For example, as part of Stage 6A, the 3D stack 430 is placed on the third die 124 such that the one or more conductive interconnects 422 are placed on the side 176 of the third die 124. Various attachment techniques can be used to attach the one or more conductive interconnects 422 to the side 176. For example, reflow is performed to melt the solder of the one or more conductive interconnects 422 to form mechanical connections with the side 176.

In some examples, via-last fabrication techniques are used to create the one or more through-via conductors 166 that extend through the third die 124. For example, openings are formed in the third die 124 from the side 186 that extend to the one or more conductive interconnects 422 on the side 176, sidewalls of the openings are insulated, and metallization operations are used to fill or line the openings to form the one or more through-via conductors 166. In some examples, the openings can be formed using laser drilling or an etching process. In some examples, the sidewalls of the openings can be insulated by depositing a thin dielectric layer using thermal oxidation or chemical vapor deposition. In some examples, the metallization operations can include filling or lining the openings with a metal (e.g., copper) using electroplating or chemical vapor deposition.

The through-via conductors 166 (e.g., conductive vias) have the pitch 167. For example, the pitch 167 corresponds to a distance between two of the through-via conductors 166 that are closest to each other (e.g., have the shortest distance to each other) among the through-via conductors 166. In a particular aspect, the distance is measured from a center (e.g., an axis of symmetry) of a first through-via conductor 166 to a center (e.g., an axis of symmetry) of a second through-via conductor 166.

The one or more conductive interconnects 424 are formed on the side 186 of the third die 124 in alignment with the one or more through-via conductors 166. In some examples, metal deposition and patterning (e.g., etching) is used to form the one or more conductive interconnects 424. In some examples, metal pads are formed on the side 186 of the third die 124 in alignment with the one or more through-via conductors 166 of the third die 124, and solder bumps are placed on the metal pads and reflow is performed to melt the solder to form electrical and mechanical connections with the one or more through-via conductors 166. Formation of a three-dimensional (3D) stack 440 is complete after Stage 6A of FIG. 4C.

In implementations in which wafer-level, panel-level, or strip-level fabrication techniques are used, singulation is performed to obtain the 3D stack 440. In an example, subsequent to forming the one or more conductive interconnects 424, integrated structures are separated (e.g., using dicing, laser ablation, laser cutting, etc.) to obtain multiple 3D stacks 440. As part of the singulation process, the 3D stack 440 can be produced having multiple dies with the same width, without additional steps or complexity. For example, the third die 124 can have the same width as the second die 122. Having the same width enables the third die 124 to provide structural support evenly across the second die 122.

Stages 5B and 6B of FIG. 4D are alternatives to Stages 5A and 6A of FIG. 4C. Stage 5B illustrates a state after alignment of the 3D stack 430 with the third die 124 that includes the one or more through-via conductors 166 and the one or more conductive interconnects 424 formed on the side 186 in alignment with the one or more through-via conductors 166. For example, as part of Stage 5B, the 3D stack 430 is aligned with the third die 124 such that the side 184 of the second die 122 is facing the side 176 of the third die 124. The third die 124 includes the one or more through-via conductors 166 that extend from the side 186 to the side 176 of the third die 124. The one or more conductive interconnects 424 are formed on the side 186 in alignment with the one or more through-via conductors 166. The 3D stack 430 is aligned with the third die 124 such that the one or more conductive interconnects 422 are aligned with the one or more through-via conductors 166.

Stage 6B illustrates a state after attachment of the one or more conductive interconnects 422 of the 3D stack 430 to the third die 124. For example, as part of Stage 6B, the 3D stack 430 is placed on the third die 124 such that the one or more conductive interconnects 422 are placed on the side 176 of the third die 124. Various attachment techniques can be used to attach the one or more conductive interconnects 422 to the side 176. For example, reflow is performed to melt the solder of the one or more conductive interconnects 422 to form electrical and mechanical connections with the one or more through-via conductors 166. Formation of a 3D stack 440 is complete after Stage 6B of FIG. 4D.

In implementations in which wafer-level, panel-level, or strip-level fabrication techniques are used, singulation is performed to obtain the 3D stack 440. In an example, subsequent to attaching the one or more conductive interconnects 422 to the one or more through-via conductors 166, integrated structures are separated (e.g., using dicing, laser ablation, laser cutting, etc.) to obtain multiple 3D stacks 440. As part of the singulation process, the 3D stack 440 can be produced having multiple dies with the same width, without additional steps or complexity. For example, the third die 124 can have the same width as the second die 122. Having the same width enables the third die 124 to provide structural support evenly across the second die 122.

In some examples, the one or more through-via conductors 166 can be formed using via-last fabrication techniques after attachment of the 3D stack 430 to the third die 124, as described with reference to FIG. 4C. In other examples, the one or more through-via conductors 166 are formed prior to attachment of the 3D stack 430 to the third die 124, as described with reference to FIG. 4D.

Stage 7 of FIG. 4E illustrates a state after coupling of the 3D stack 440 to the substrate 102. For example, as part of Stage 7, one or more conductive interconnects 426 are formed on the one or more conductive interconnects 424. In some examples, the one or more conductive interconnects 426 include solder balls, microbumps, pillars, pads, or other types of conductive interconnects. The 3D stack 440 is positioned with the one or more conductive interconnects 426 on the substrate 102. Various attachment techniques can be used to attach the one or more conductive interconnects 426 to the substrate 102. For example, the one or more conductive interconnects 426 can include solder balls and reflow is performed to attach the one or more conductive interconnects 426 to the substrate 102.

Stage 8 of FIG. 4F illustrates a state after formation of the one or more conductive interconnects 428 on a side 482 of the substrate 102. For example, as part of Stage 8, a ball grid array (BGA) is formed on the substrate 102. The BGA may include the one or more conductive interconnects 426, such as solder balls, and BGA attach operation may be performed to couple the one or more conductive interconnects 426 to the substrate 102, such as to one or more contacts on the side 482 of the substrate 102. Solder balls are provided as an illustrative example; in other examples the one or more conductive interconnects 428 can include microbumps, pillars, pads, or other types of conductive interconnects.

In a particular aspect, the device 100 includes a conductive path from the first active circuitry 142 of the first die 120A via the one or more conductive vias 320, the RDL 144A, the one or more conductive interconnects 420, and the RDL 154, to the metal layers 180 of the second active circuitry 152. The device 100 includes a conductive path from the first metal layer (e.g., M1) of the metal layers 180 of the second active circuitry 152 to the one or more conductive interconnects 428. For example, the conductive path can include the one or more conductive vias 156, the one or more conductive interconnects 422, the one or more through-via conductors 166, the one or more conductive interconnects 424, the one or more conductive interconnects 426, and conductors of the substrate 102. In some aspects, the one or more conductive interconnects 428 correspond to package contacts (e.g., a ball grid array) that are configured to be electrically coupled to off-package components.

Formation of the device 100 is complete after Stage 8 of FIG. 4F. Although certain Stages are illustrated in FIGS. 4A-4F in forming the device 100, other processes can be included in the fabrication of the device 100 without departing from the scope of the subject disclosure.

Each of the various stages of the sequence illustrated in FIGS. 5A-5F shows one or more stacked IC devices being formed. In other implementations, a single IC device may be formed or a plurality of IC devices can be formed concurrently.

Stage 1 of FIG. 5A illustrates a state after attaching the second die 122 to a carrier wafer 502. For example, as part of Stage 1, the side 174 of the second die 122 is attached to the carrier wafer 502. The metal layers 180 of the second active circuitry 152 are proximate to the side 174. The RDL 154 is between the metal layers 180 and the carrier wafer 502. The second die 122 can be attached to the carrier wafer 502 using various attachment techniques. For example, in some aspects, an adhesive layer is applied to the carrier wafer 502 and the side 174 of the second die 122 is placed on the adhesive layer. In some other aspects, a removable tape or mechanical clamp may be used.

Stage 2 illustrates a state after thinning of the second die 122 and formation of the one or more conductive vias 156 that extend from the side 184 of the second die 122 to a first metal layer (e.g., M1) of the metal layers 180 that is closest to the side 184 among the metal layers 180. For example, as part of Stage 2, the second die 122 is thinned to a target second thickness (e.g., 3 μm). After thinning the second die 122, openings are formed (e.g., using laser drilling or etching processes) in the second die 122 from the side 184, sidewalls of the openings are insulated, and metallization operations are used to fill or line the openings to form the one or more conductive vias 156. The conductive vias 156 have the pitch 157.

Stage 3 illustrates a state after planarization of the one or more conductive vias 156 and formation of the one or more conductive interconnects 422 in alignment with the one or more conductive vias 156. For example, as part of Stage 3, chemical mechanical polishing can be used to planarize a surface of the second die 122 including the one or more conductive vias 156. In some examples, metal deposition and patterning (e.g., etching) are used to form the one or more conductive interconnects 422. In some examples, metal pads are formed on the side 184 of the second die 122 in alignment with the one or more conductive vias 156 of the second die 122, and solder bumps are placed on the metal pads and reflow is performed to melt the solder to form electrical and mechanical connections with the one or more conductive vias 156.

It should be understood that a conductive interconnect 422 formed in contact with a single conductive via 156 is provided as an illustrative example; in other examples a conductive interconnect 422 is formed in contact with a set of multiple conductive vias 156 of the second die 122.

Stage 4 of FIG. 5B illustrates a state after alignment of the die stack 330 with the second die 122. For example, as part of Stage 4, the die stack 330 is aligned with the second die 122 such that the one or more conductive interconnects 420 on the side 182 of the first die 120A are facing and aligned with the one or more conductive interconnects 422 on the side 184 of the second die 122.

Stage 5 illustrates a state after attachment of the one or more conductive interconnects 420 on the side 182 of the first die 120A to the one or more conductive interconnects 422 on the side 184 of the second die 122. For example, as part of Stage 5, the one or more conductive interconnects 420 of the die stack 330 are placed on the side 184 of the second die 122. Various attachment techniques can be used to attach the one or more conductive interconnects 420 of the die stack 330 to the one or more conductive interconnects 422 on the side 184 of the second die 122. For example, reflow is performed to melt the solder of the one or more conductive interconnects 420 to form electrical and mechanical connections with the one or more conductive interconnects 422. Formation of a 3D stack 530 is complete after Stage 5 of FIG. 5B.

Stage 6A of FIG. 5C illustrates a state after alignment of the 3D stack 530 with the third die 124. For example, as part of Stage 6A, the 3D stack 530 is aligned with the third die 124 such that the RDL 154 on the side 174 of the second die 122 is facing the side 176 of the third die 124. In some aspects, the third die 124 is devoid of active circuitry. In some aspects, the third die 124 may include other circuitry, such as passive circuitry (e.g., capacitors, inductors, resistors).

Stage 7A illustrates a state after attachment of the RDL 154 to the third die 124, formation of the one or more through-via conductors 166 that extend through the third die 124, and formation of the one or more conductive interconnects 424 that are aligned with the one or more through-via conductors 166. For example, as part of Stage 7A, the 3D stack 530 is placed on the third die 124 such that the RDL 154 of the second die 122 is placed on the side 176 of the third die 124. Various attachment techniques can be used to attach the RDL 154 to the side 176 of the third die 124. For example, a surface of the RDL 154 may be coated with a passivation layer, leaving openings at designated contact points, and solder bumps may be deposited on the openings or on the side 176 in alignment with the openings. Reflow may be performed to melt the solder to form mechanical connections between the RDL 154 and the side 176.

In some examples, via-last fabrication techniques are used to create the one or more through-via conductors 166 that extend through the third die 124, as described with reference to Stage 6A of FIG. 4C. The one or more conductive interconnects 424 are formed on the side 186 of the third die 124 in alignment with the one or more through-via conductors 166, as described with reference to Stage 6A of FIG. 4C. The through-via conductors 166 have the pitch 167.

In implementations in which wafer-level, panel-level, or strip-level fabrication techniques are used, singulation is performed to obtain the 3D stack 540. In an example, subsequent to forming the one or more conductive interconnects 424, integrated structures are separated (e.g., using dicing, laser ablation, laser cutting, etc.) to obtain multiple 3D stacks 540. As part of the singulation process, the 3D stack 540 can be produced having multiple dies with the same width, without additional steps or complexity. For example, the third die 124 can have the same width as the second die 122. Having the same width enables the third die 124 to provide structural support evenly across the second die 122.

Stages 6B and 7B of FIG. 5D are alternatives to Stages 6A and 7A of FIG. 5C. Stage 6B illustrates a state after alignment of the 3D stack 530 with the third die 124 that includes the one or more through-via conductors 166 and the one or more conductive interconnects 424 formed on the side 186 in alignment with the one or more through-via conductors 166. For example, as part of Stage 6B, the 3D stack 530 is aligned with the third die 124 such that the RDL 154 on the side 174 of the second die 122 is facing the side 176 of the third die 124. The third die 124 includes the one or more through-via conductors 166 that extend from the side 186 to the side 176 of the third die 124. The one or more conductive interconnects 424 are formed on the side 186 in alignment with the one or more through-via conductors 166.

Stage 7B illustrates a state after attachment of the RDL 154 of the 3D stack 530 to the side 176 of the third die 124. For example, as part of Stage 7B, the 3D stack 540 is placed on the third die 124 such that the RDL 154 of the second die 122 is placed on the side 176 of the third die 124. Various attachment techniques can be used to attach the RDL 154 to the side 176 of the third die 124, as described with reference to Stage 7A of FIG. 5C. Formation of a 3D stack 540 is complete after Stage 7B of FIG. 5D.

In implementations in which wafer-level, panel-level, or strip-level fabrication techniques are used, singulation is performed to obtain the 3D stack 540. In an example, subsequent to attaching the RDL 154 to the one or more through-via conductors 166, integrated structures are separated (e.g., using dicing, laser ablation, laser cutting, etc.) to obtain multiple 3D stacks 540. As part of the singulation process, the 3D stack 540 can be produced having multiple dies with the same width, without additional steps or complexity. For example, the third die 124 can have the same width as the second die 122. Having the same width enables the third die 124 to provide structural support evenly across the second die 122.

In some examples, the one or more through-via conductors 166 can be formed using via-last fabrication techniques after attachment of the 3D stack 530 to the third die 124, as described with reference to FIG. 5C. In other examples, the one or more through-via conductors 166 are formed prior to attachment of the 3D stack 530 to the third die 124, as described with reference to FIG. 5D.

Stage 8 of FIG. 5E illustrates a state after coupling of the 3D stack 540 to the substrate 102. For example, as part of Stage 8, one or more conductive interconnects 426 are formed on the one or more conductive interconnects 424 and are attached to the substrate 102, as described with reference to Stage 7 of FIG. 4E.

Stage 9 of FIG. 5F illustrates a state after formation of the one or more conductive interconnects 428 on the side 482 of the substrate 102. For example, as part of Stage 9, the one or more conductive interconnects 428 may be formed on the substrate 102, as described with reference to Stage 8 of FIG. 4F.

In a particular aspect, the device 200 includes a conductive path from the first active circuitry 142 of the first die 120A via the one or more conductive vias 320, the RDL 144A, the one or more conductive interconnects 420, the one or more conductive interconnects 422, and the one or more conductive vias 156, to a first metal layer (e.g., M1) of the metal layers 180 of the second active circuitry 152. The device 200 includes a conductive path from the metal layers 180 of the second active circuitry 152 to the one or more conductive interconnects 428. For example, the conductive path can include the RDL 154, the one or more through-via conductors 166, the one or more conductive interconnects 424, the one or more conductive interconnects 426, and conductors of the substrate 102. In some aspects, the one or more conductive interconnects 428 correspond to package contacts (e.g., a ball grid array) that are configured to be electrically coupled to off-package components.

Formation of the device 200 is complete after Stage 9 of FIG. 5F. Although certain Stages are illustrated in FIGS. 5A-5F in forming the device 200, other processes can be included in the fabrication of the device 200 without departing from the scope of the subject disclosure.

FIG. 6A illustrates a cross-sectional profile view of a portion 600 of the device 100 of FIG. 1. The portion 600 includes a bonding interface 622 between the side 182 of the first die 120A and the side 174 of the second die 122. In some aspects, the bonding interface 622 includes the RDL 144A, the one or more conductive interconnects 420, the RDL 154, or a combination thereof.

The first die 120A includes metal layers 680 that are electrically coupled via the bonding interface 622 to the metal layers 180 of the second die 122. In some aspects, the metal layers 680 include a first metal layer (e.g., M1) that is closest among the metal layers 680 to the side 172 of the first die 120A (e.g., the back of the first die 120A). The first die 120A includes a conductive via 656 that lands on the first metal layer (e.g., M1) of the metal layers 680. In some aspects, the one or more conductive vias 320 of FIG. 3A include the conductive via 656. For example, the conductive via 656 can be formed using via-last fabrication techniques.

The metal layers 180 include a metal layer 682 (e.g., M1) that is closest among the metal layers 180 to the side 184 of the second die 122 (e.g., the back of the second die 122). The second die 122 includes the conductive via 156 that lands on the metal layer 682 (e.g., M1) of the metal layers 180. For example, the conductive via 156 can be formed using via-last fabrication techniques.

FIG. 6B illustrates a cross-sectional profile view of a portion 650 of the device 200 of FIG. 2. The portion 650 includes the bonding interface 622 between the side 182 of the first die 120A (e.g., the face of the first die 120A) and the side 184 of the second die 122 (e.g., the back of the second die 122).

The first die 120A includes the metal layers 680 that are electrically coupled via the bonding interface 622 to the metal layers 180 of the second die 122. For example, the portion 650 of the device 200 includes a conductive path from the bonding interface 622, through the one or more conductive interconnects 422 and the one or more conductive vias 156, to the metal layer 682 of the metal layers 180.

### Exemplary Flow Diagrams of Methods for Fabricating a Stacked Integrated Circuit Device Including a Stiffener Die

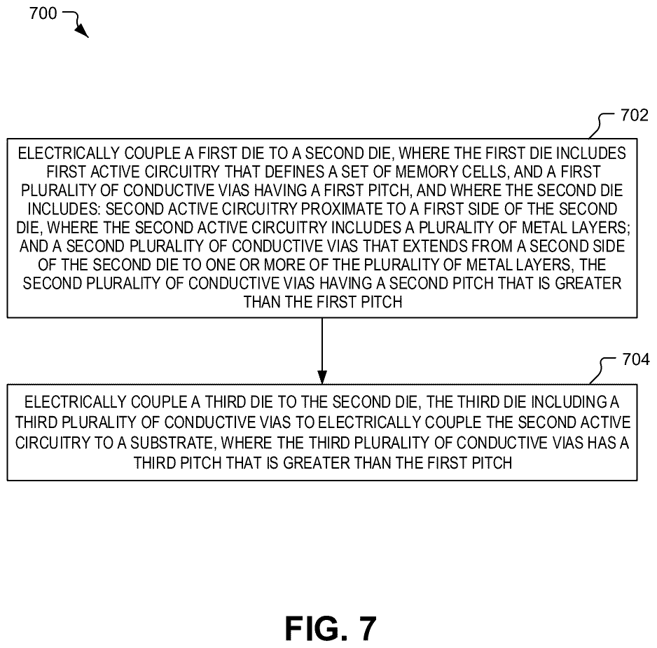

In some implementations, fabricating a stacked IC device includes several processes. FIG. 7 illustrates an exemplary flow diagram of a method 700 of fabricating an illustrative device that includes a stiffener die. In a particular aspect, one or more operations of the method 700 are performed by one or more processors of a fabrication system. In some implementations, operations of the method 700 may be stored as instructions by a non-transitory computer-readable storage medium, and the instructions may be executable by at least one processor to cause the at least one processor to perform operations of the method 700. In some implementations, the method 700 of FIG. 7 may be used to provide or fabricate any of the device 100 or the device 200 of FIGS. 1 and 2.

It should be noted that the method 700 of FIG. 7 may combine one or more processes in order to simplify and/or clarify the method for providing or fabricating an integrated circuit device. In some implementations, the order of the processes may be changed or modified.

The method 700 includes, at block 702, electrically coupling a first die to a second die. For example, Stage 2 of FIG. 4A and Stage 5 of FIG. 5B illustrate and describe examples of electrically coupling one or more first dies 120 to the second die 122. The first die 120A includes the first active circuitry 142A, which in some examples, defines a set of memory cells. The first die 120A includes the conductive vias 320 having the pitch 121. The second die 122 includes the second active circuitry 152 proximate to the side 174 of the second die 122. The second active circuitry 152 includes the metal layers 180. The second die 122 also includes the conductive vias 156 that extend from the side 184 of the second die 122 to one or more (e.g., the metal layer 682) of the metal layers 180. The conductive vias 156 have the pitch 157 that is greater than the pitch 121.

The method 700 includes, at block 704, electrically coupling a third die to the second die. For example, Stage 6A of FIG. 4C, Stage 6B of 4D, Stage 7A of FIG. 5C, and Stage 7B of FIG. 5D illustrate and describe examples of electrically coupling the third die 124 to the second die 122. The third die 124 includes the through-via conductors 166 to electrically couple the second active circuitry 152 to the substrate 102. The through-via conductors 166 have the pitch 167 that is greater than the pitch 121.

In some implementations, at least one of the one or more first dies 120 includes a memory die, the second die 122 includes a memory controller die, and the third die 124 includes a base die.

In some implementations, the method 700 includes forming the one or more conductive vias 156 of the second die 122 subsequent to electrically coupling the one or more first dies 120 to the second die 122. For example, Stage 3 of FIG. 4B illustrates and describes examples of forming the one or more conductive vias 156 of the second die 122 subsequent to electrically coupling the one or more first dies 120 to the second die 122.

In some implementations, the method 700 includes forming the one or more conductive vias 156 of the second die 122 prior to electrically coupling the one or more first dies 120 to the second die 122. For example, Stage 2 of FIG. 5A illustrates and describes examples of forming the one or more conductive vias 156 of the second die 122 prior to electrically coupling the one or more first dies 120 to the second die 122. Similarly in some implementations, as described in an alternative to Stages 3-4 of FIG. 4B, the one or more conductive vias 156 can be formed prior to electrically coupling the one or more first dies 120 to the second die 122.

In some implementations, the method 700 includes forming the one or more through-via conductors 166 of the third die 124 subsequent to electrically coupling the third die 124 to the second die 122. For example, Stage 6A of FIG. 4C and Stage 7A of FIG. 5C illustrate and describe examples of forming the one or more through-via conductors 166 of the third die 124 subsequent to electrically coupling the third die 124 to the second die 122.

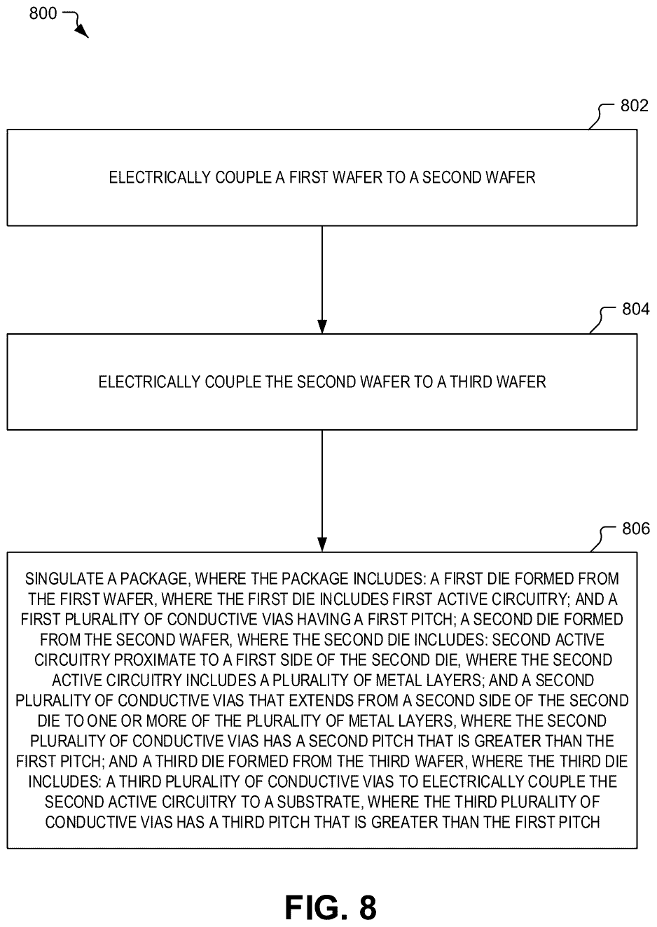

FIG. 8 illustrates an exemplary flow diagram of a method 800 of fabricating an illustrative device that includes a conductive via in an intermediate die that extends from a side to the closest active circuitry metal layer of the die. In a particular aspect, one or more operations of the method 800 are performed by one or more processors of a fabrication system. In some implementations, operations of the method 800 may be stored as instructions by a non-transitory computer-readable storage medium, and the instructions may be executable by at least one processor to cause the at least one processor to perform operations of the method 800. In some implementations, the method 800 of FIG. 8 may be used to provide or fabricate any of the device 100 or the device 200 of FIGS. 1 and 2.

It should be noted that the method 800 of FIG. 8 may combine one or more processes in order to simplify and/or clarify the method for providing or fabricating an integrated circuit device. In some implementations, the order of the processes may be changed or modified.

The method 800 includes, at block 802, electrically coupling a first wafer to a second wafer. For example, Stage 2 of FIG. 4A and Stage 5 of FIG. 5B describe examples of electrically coupling one or more first dies 120 to the second die 122. In wafer-level fabrication, a first wafer includes or defines multiple instances of the one or more first dies 120, a second wafer includes or defines multiple instances of the second die 122, and the first wafer is electrically coupled to the second wafer. For example, the one or more conductive interconnects 420 of the first wafer are attached to the RDL 154 of the second wafer, as described with reference to Stage 2 of FIG. 4A. As another example, the one or more conductive interconnects 420 of the first wafer are attached to the one or more conductive interconnects 422 of the second wafer, as described with reference to Stage 4 of FIG. 5B.

The method 800 includes, at block 804, electrically coupling the second wafer to a third wafer. For example, Stage 6A of FIG. 4C, Stage 6B of 4D, Stage 7A of FIG. 5C, and Stage 7B of FIG. 5D describe examples of electrically coupling the second die 122 to the third die 124. In wafer-level fabrication, the second wafer includes or defines multiple instances of the second die 122, a third wafer includes or defines multiple instances of the third die 124, and the second wafer is electrically coupled to the third wafer. For example, the one or more conductive interconnects 422 of the second wafer are attached to the third die 124 of the third wafer, as described with reference to Stage 6A of FIG. 4C. As another example, the one or more conductive interconnects 422 of the second wafer are attached to the one or more through-via conductors 166 of the third wafer, as described with reference to Stage 6B of FIG. 4D. As another example, the RDL 154 of the second wafer is attached to the third die 124 of the third wafer, as described with reference to Stage 7B of FIG. 5D. As yet another example, the RDL 154 of the second wafer is attached to the one or more through-via conductors 166 of the third wafer, as described with reference to Stage 7B of FIG. 5D.

The method 800 includes, at block 806, singulating a package. For example, prior to Stage 7 of FIG. 4E, singulation is performed to obtain the device 100 (e.g., an IC package). As another example, prior to Stage 8 of FIG. 5E, singulation is performed to obtain the device 200 (e.g., an IC package). The package (e.g., the device 100 or the device 200) includes the one or more first dies 120 formed from the first wafer, the second die 122 formed from the second wafer, and the third die 124 formed from the third wafer. The first die 120A includes the first active circuitry 142A and the conductive vias 320 having the pitch 121. The second die 122 includes second active circuitry 152 proximate to the side 174 of the second die 122. The second active circuitry 152 includes the metal layers 180. The second die 122 includes the conductive vias 156 that extend from the side 184 of the second die 122 to one or more (e.g., the metal layer 682) of the metal layers 180. The conductive vias 156 have the pitch 157 that is greater than the pitch 121. The third die 124 includes the through-via conductors 166 to electrically couple the second active circuitry 152 to the substrate 102. The through-via conductors 166 have the pitch 167 that is greater than the pitch 121.

In some implementations, at least one of the one or more first dies 120 includes a memory die, the second die 122 includes a memory controller die, and the third die 124 includes a base die.

### Exemplary Electronic Devices

FIG. 9 illustrates various electronic devices that may include or be integrated with any of the device 100 or the device 200 (that includes a conductive via in an intermediate die that extends from a side to the closest active circuitry metal layer of the die). For example, a mobile phone device 902, a laptop computer device 904, a fixed location terminal device 906, a wearable device 908, or a vehicle 910 (e.g., an automobile or an aerial device) may include a device 900. The device 900 can include, for example, any of the device 100 or the device 200, and/or any other integrated device that includes a conductive structure described herein. The devices 902, 904, 906 and 908 and the vehicle 910 illustrated in FIG. 9 are merely exemplary. Other electronic devices may also feature the device 900 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1-9 may be rearranged and/or combined into a single component, process, feature or function or embodied in several components, processes, or functions. Additional elements, components, processes, and/or functions may also be added without departing from the disclosure. It should also be noted FIGS. 1-9 and its corresponding description in the present disclosure is not limited to dies and/or ICs. In some implementations, FIGS. 1-9 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately ‘value X’”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the terms “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a stacked integrated circuit (IC) device includes a first die that includes first active circuitry that defines a set of memory cells; a second die electrically coupled to the first die, wherein the second die includes: second active circuitry proximate to a first side of the second die, wherein the second active circuitry includes a plurality of metal layers; a conductive via that extends from a second side of the second die to a first metal layer of the plurality of metal layers, the first metal layer closest among the plurality of metal layers to the second side of the second die; and a third die electrically coupled to the second die, wherein the third die includes a through-via conductor to electrically couple the second active circuitry to a substrate, wherein the second die is disposed between the first die and the third die.

Example 2 includes the stacked IC device of Example 1, wherein the first die includes a memory die, the second die includes a memory controller die, and the third die includes a base die.

Example 3 includes the stacked IC device of Example 1 or Example 2, wherein the conductive via is aligned with the through-via conductor.

Example 4 includes the stacked IC device of any of Examples 1 to 3, wherein the second die includes a set of multiple conductive vias, and wherein the set is aligned with the through-via conductor.

Example 5 includes the stacked IC device of any of Examples 1 to 4, and further includes a conductive path from the first metal layer through the conductive via and the through-via conductor to the substrate.

Example 6 includes the stacked IC device of any of Examples 1 to 5, wherein the third die is devoid of active circuitry.

Example 7 includes the stacked IC device of any of Examples 1 to 6, wherein a thickness of the second die is less than a thickness of the first die and less than a thickness of the third die.

Example 8 includes the stacked IC device of any of Examples 1 to 7, wherein a characteristic dimension of the through-via conductor is greater than a corresponding characteristic dimension of the conductive via.

Example 9 includes the stacked IC device of any of Examples 1 to 8, wherein the second die and the third die have a same width.

Example 10 includes the stacked IC device of any of Examples 1 to 9, wherein the first die, the second die, and the third die have a same width.

Example 11 includes the stacked IC device of any of Examples 1 to 10, wherein the first side of the second die is adjacent to a first side of the first die.

Example 12 includes the stacked IC device of any of Examples 1 to 11, wherein the second die includes a redistribution layer (RDL), wherein the RDL is disposed between the first die and the second active circuitry of the second die.

Example 13 includes the stacked IC device of any of Examples 1 to 10, wherein the first side of the second die is adjacent to a first side of the third die.

Example 14 includes the stacked IC device of any of Examples 1 to 10 or 13, wherein the second die includes a redistribution layer (RDL), wherein the RDL is disposed between the third die and the second active circuitry of the second die.

Example 15 includes the stacked IC device of any of Examples 1 to 14, wherein the second active circuitry includes memory control circuitry.

Example 16 includes the stacked IC device of any of Examples 1 to 15, wherein the second active circuitry includes physical interface circuitry.

Example 17 includes the stacked IC device of any of Examples 1 to 16, wherein the third die mechanically supports the second die to resist delamination.

According to Example 18, a method of fabrication includes electrically coupling a first die to a second die, wherein the first die includes first active circuitry that defines a set of memory cells, and wherein the second die includes: second active circuitry proximate to a first side of the second die, wherein the second active circuitry includes a plurality of metal layers; and a conductive via that extends from a second side of the second die to a first metal layer of the plurality of metal layers, the first metal layer closest among the plurality of metal layers to the second side of the second die; and electrically coupling a third die to the second die, the third die including a through-via conductor to electrically couple the second active circuitry to a substrate.

Example 19 includes the method of Example 18, wherein the first die includes a memory die, the second die includes a memory controller die, and the third die includes a base die.

Example 20 includes the method of Example 18 or Example 19, and further includes forming the conductive via of the second die subsequent to electrically coupling the first die to the second die.

Example 21 includes the method of Example 18 or Example 19, and further includes forming the conductive via of the second die prior to electrically coupling the first die to the second die.

Example 22 includes the method of any of Examples 18 to 21, and further includes forming the through-via conductor of the third die subsequent to electrically coupling the third die to the second die.

According to Example 23, a method of fabrication includes electrically coupling a first wafer to a second wafer; electrically coupling the second wafer to a third wafer; and singulating a stacked integrated circuit device, wherein the stacked integrated circuit device includes: a first die formed from the first wafer, wherein the first die includes first active circuitry that defines a set of memory cells; a second die formed from the second wafer, wherein the second die includes: second active circuitry proximate to a first side of the second die, wherein the second active circuitry includes a plurality of metal layers; and a conductive via that extends from a second side of the second die to a first metal layer of the plurality of metal layers, the first metal layer closest among the plurality of metal layers to the second side of the second die; and a third die formed from the third wafer, the third die including a through-via conductor to electrically couple the second active circuitry to a substrate.

Example 24 includes the method of Example 23, wherein the first die includes a memory die, the second die includes a memory controller die, and the third die includes a base die.

According to Example 25, a package includes a first die that includes: first active circuitry; and a first plurality of conductive vias that has a first pitch; a second die electrically coupled to the first die, wherein the second die includes: second active circuitry proximate to a first side of the second die, wherein the second active circuitry includes a plurality of metal layers; and a second plurality of conductive vias that extends from a second side of the second die to one or more of the plurality of metal layers, wherein the second plurality of conductive vias has a second pitch that is greater than the first pitch; and a third die electrically coupled to the second die, wherein the third die includes: a third plurality of conductive vias to electrically couple the second active circuitry to a substrate, wherein the third plurality of conductive vias has a third pitch that is greater than the first pitch, wherein the second die is disposed between the first die and the third die.

Example 26 includes the package of Example 25, wherein the first active circuitry defines a set of memory cells, and wherein the third pitch is greater than or equal to the second pitch.

Example 27 includes the package of Example 25 or Example 26, wherein the first side of the second die is adjacent to a second side of the first die, wherein the second side of the second die is adjacent to a first side of the third die, and wherein each of the second side of the first die, the first side of the second die, the second side of the second die, and the first side of the third die has the same dimensions.

Example 28 includes the package of any of Examples 25 to 27, wherein the second plurality of conductive vias extends from the second side of the second die to a first metal layer of the plurality of metal layers, and wherein the first metal layer is closest among the plurality of metal layers to the second side of the second die.

Example 29 includes the package of Example 28, wherein the first metal layer is electrically coupled through one of the second plurality of conductive vias and one of the third plurality of conductive vias to the substrate.

Example 30 includes the package of any of Examples 25 to 29, wherein the first pitch corresponds to a distance between a pair of conductive vias that are closest to each other among the first plurality of conductive vias, wherein the second pitch corresponds to a distance between a pair of conductive vias that are closest to each other among the second plurality of conductive vias, and wherein the second pitch is 2 to 30 times greater than the first pitch.

Example 31 includes the package of any of Examples 25 to 30, wherein the first die includes a memory die, the second die includes a memory controller die, and the third die includes a base die.

Example 32 includes the package of any of Examples 25 to 31, wherein at least one of the second plurality of conductive vias of the second die is aligned with a respective one of the third plurality of conductive vias of the third die.

Example 33 includes the package of any of Examples 25 to 32, wherein the second die is a chiplet.

Example 34 includes the stacked IC device of any of Examples 25 to 33, wherein the third die is devoid of active circuitry.

Example 35 includes the package of any of Examples 25 to 34, wherein a thickness of the second die is less than a thickness of the first die and less than a thickness of the third die.

Example 36 includes the package of any of Examples 25 to 35, wherein a width of at least one of the third plurality of conductive vias is greater than a width of at least one of the second plurality of conductive vias.

Example 37 includes the package of any of Examples 25 to 36, wherein the second die includes a redistribution layer (RDL), wherein the RDL is disposed between the first die and the second active circuitry of the second die.

Example 38 includes the package of any of Examples 25 to 37, wherein the second die includes a redistribution layer (RDL), wherein the RDL is disposed between the third die and the second active circuitry of the second die.

Example 39 includes the package of any of Examples 25 to 38, wherein the second active circuitry includes memory control circuitry, physical interface circuitry, or both.

Example 40 includes the package of any of Examples 25 to 39, wherein the third die mechanically supports the second die to resist delamination.

Example 41 includes the package of any of Examples 25 to 40, wherein the first die, the second die, and the third die are integrated into a mobile device, a hand-held personal communication system (PCS) unit, a portable data unit, a global positioning system (GPS) enabled device, a navigation device, a set top box, a music player, a video player, an entertainment unit, a fixed location data unit, a communications device, a smartphone, a tablet computer, a computer, a wearable device, an Internet of things (IoT) device, a server, a router, a vehicle, or a combination thereof.

According to Example 42, a method of fabrication includes electrically coupling a first die to a second die, wherein the first die includes: first active circuitry, and a first plurality of conductive vias having a first pitch; and wherein the second die includes: second active circuitry proximate to a first side of the second die, wherein the second active circuitry includes a plurality of metal layers; and a second plurality of conductive vias that extends from a second side of the second die to one or more of the plurality of metal layers, the second plurality of conductive vias having a second pitch that is greater than the first pitch; and electrically coupling a third die to the second die, the third die including: a third plurality of conductive vias to electrically couple the second active circuitry to a substrate, wherein the third plurality of conductive vias has a third pitch that is greater than the first pitch.

Example 43 includes the method of Example 42, further comprising forming the second plurality of conductive vias of the second die subsequent to electrically coupling the first die to the second die.

According to Example 44, a method of fabrication includes electrically coupling a first wafer to a second wafer; electrically coupling the second wafer to a third wafer; and singulating a package, wherein the package includes: a first die formed from the first wafer, wherein the first die includes: first active circuitry; and a first plurality of conductive vias having a first pitch; a second die formed from the second wafer, wherein the second die includes: second active circuitry proximate to a first side of the second die, wherein the second active circuitry includes a plurality of metal layers; and a second plurality of conductive vias that extends from a second side of the second die to one or more of the plurality of metal layers, wherein the second plurality of conductive vias has a second pitch that is greater than the first pitch; and a third die formed from the third wafer, the third die including: a third plurality of conductive vias to electrically couple the second active circuitry to a substrate, wherein the third plurality of conductive vias has a third pitch that is greater than the first pitch.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A package comprising:
a first die that includes:
first active circuitry; and
a first plurality of conductive vias that has a first pitch;
a second die electrically coupled to the first die, wherein the second die includes:
second active circuitry proximate to a first side of the second die, wherein the second active circuitry includes a plurality of metal layers; and
a second plurality of conductive vias that extends from a second side of the second die to one or more of the plurality of metal layers, wherein the second plurality of conductive vias has a second pitch that is greater than the first pitch; and
a third die electrically coupled to the second die, wherein the third die includes:
a third plurality of conductive vias to electrically couple the second active circuitry to a substrate, wherein the third plurality of conductive vias has a third pitch that is greater than the first pitch,
wherein the second die is disposed between the first die and the third die.

2. The package of claim 1, wherein the first active circuitry defines a set of memory cells, and wherein the third pitch is greater than or equal to the second pitch.

3. The package of claim 1, wherein the first side of the second die is adjacent to a second side of the first die, wherein the second side of the second die is adjacent to a first side of the third die, and wherein each of the second side of the first die, the first side of the second die, the second side of the second die, and the first side of the third die has the same dimensions.

4. The package of claim 1, wherein the second plurality of conductive vias extends from the second side of the second die to a first metal layer of the plurality of metal layers, and wherein the first metal layer is closest among the plurality of metal layers to the second side of the second die.

5. The package of claim 4, wherein the first metal layer is electrically coupled through one of the second plurality of conductive vias and one of the third plurality of conductive vias to the substrate.

6. The package of claim 1, wherein the first pitch corresponds to a distance between a pair of conductive vias that are closest to each other among the first plurality of conductive vias, wherein the second pitch corresponds to a distance between a pair of conductive vias that are closest to each other among the second plurality of conductive vias, and wherein the second pitch is 2 to 30 times greater than the first pitch.

7. The package of claim 1, wherein the first die includes a memory die, the second die includes a memory controller die, and the third die includes a base die.

8. The package of claim 1, wherein at least one of the second plurality of conductive vias of the second die is aligned with a respective one of the third plurality of conductive vias of the third die.

9. The package of claim 1, wherein the second die is a chiplet.

10. The package of claim 1, wherein the third die is devoid of active circuitry.

11. The package of claim 1, wherein a thickness of the second die is less than a thickness of the first die and less than a thickness of the third die.

12. The package of claim 1, wherein a width of at least one of the third plurality of conductive vias is greater than a width of at least one of the second plurality of conductive vias.

13. The package of claim 1, wherein the second die includes a redistribution layer (RDL), wherein the RDL is disposed between the first die and the second active circuitry of the second die.

14. The package of claim 1, wherein the second die includes a redistribution layer (RDL), wherein the RDL is disposed between the third die and the second active circuitry of the second die.

15. The package of claim 1, wherein the second active circuitry includes memory control circuitry, physical interface circuitry, or both.

16. The package of claim 1, wherein the third die mechanically supports the second die to resist delamination.

17. The package of claim 1, wherein the first die, the second die, and the third die are integrated into a mobile device, a hand-held personal communication system (PCS) unit, a portable data unit, a global positioning system (GPS) enabled device, a navigation device, a set top box, a music player, a video player, an entertainment unit, a fixed location data unit, a communications device, a smartphone, a tablet computer, a computer, a wearable device, an Internet of things (IoT) device, a server, a router, a vehicle, or a combination thereof.

18. A method of fabrication, the method comprising:
electrically coupling a first die to a second die,
wherein the first die includes:
first active circuitry, and
a first plurality of conductive vias having a first pitch; and
wherein the second die includes:
second active circuitry proximate to a first side of the second die, wherein the second active circuitry includes a plurality of metal layers; and
a second plurality of conductive vias that extends from a second side of the second die to one or more of the plurality of metal layers, the second plurality of conductive vias having a second pitch that is greater than the first pitch; and
electrically coupling a third die to the second die, the third die including: a third plurality of conductive vias to electrically couple the second active circuitry to a substrate, wherein the third plurality of conductive vias has a third pitch that is greater than the first pitch.

19. The method of claim 18, further comprising forming the second plurality of conductive vias of the second die subsequent to electrically coupling the first die to the second die.

20. A method of fabrication, the method comprising:
electrically coupling a first wafer to a second wafer;
electrically coupling the second wafer to a third wafer; and
singulating a package, wherein the package includes:
a first die formed from the first wafer, wherein the first die includes:
first active circuitry; and
a first plurality of conductive vias having a first pitch;
a second die formed from the second wafer, wherein the second die includes:
second active circuitry proximate to a first side of the second die, wherein the second active circuitry includes a plurality of metal layers; and
a second plurality of conductive vias that extends from a second side of the second die to one or more of the plurality of metal layers, wherein the second plurality of conductive vias has a second pitch that is greater than the first pitch; and
a third die formed from the third wafer, the third die including: a third plurality of conductive vias to electrically couple the second active circuitry to a substrate, wherein the third plurality of conductive vias has a third pitch that is greater than the first pitch.
